(19) United States
(12) Patent Application Publication
(10) Pub. No.: US 2026/0163488 A1
(43) Pub. Date: Jun. 11, 2026

(54) SWITCHING POWER SUPPLY, SELF-POWERED CIRCUIT BASED ON CCM, AND SELF-POWERED CIRCUIT BASED ON DCM

(71) Applicant: LII SEMICONDUCTOR CO., LTD, Shenzhen (CN)

(72) Inventors: Jie ZHANG, Shenzhen (CN); Min ZHU, Shenzhen (CN); Lingbo ZHENG, Shenzhen (CN)

(73) Assignee: LII SEMICONDUCTOR CO., LTD, Shenzhen (CN)

(21) Appl. No.: 19/181,704

(22) Filed: Apr. 17, 2025

Related U.S. Application Data
(63) Continuation of application No. PCT/CN2023/098419, filed on Jun. 5, 2023.

(30) Foreign Application Priority Data
Oct. 27, 2022 (CN) 202211326752.8

(51) Int. Cl. H02M 3/335; G01R 19/00; G01R 19/165; H02M 1/00; H02M 1/08; H02M 1/32

(52) U.S. Cl. CPC H02M 3/33515; G01R 19/0053; G01R 19/1659; H02M 1/0006; H02M 1/0009; H02M 1/08; H02M 1/32

(57) ABSTRACT

Disclosed are a switching power supply and a self-powered circuit based on continuous conduction mode (CCM) and a self-powered circuit based on discontinuous conduction mode (DCM). The self-powered circuit based on CCM is applied to a flyback switching power supply, and includes a voltage-resistant switching transistor, a charging branch and a charging control unit. The voltage-resistant switching transistor is connected in series between the primary coil and the charging branch to obtain the power supply voltage of the primary coil and output the charging voltage for charging the charging branch. The charging branch includes a charging capacitor configured to power the switching power supply chip and a charging switching transistor configured to control whether the charging capacitor is charged, and the charging switching transistor is connected between the charging capacitor and the voltage-resistant switching transistor. The charging control unit is configured to control whether the charging branch is turned on.

### CROSS-REFERENCE TO RELATED APPLICATIONS

This application is a continuation application of International Application No. PCT/CN2023/098419, filed on Jun. 5, 2023, which claims priority to Chinese Patent Application No. 202211326752.8, filed on Oct. 27, 2022. The disclosures of the above-mentioned applications are incorporated herein by reference in their entireties.

### TECHNICAL FIELD

The present application relates to the technical field of switching power supply control, and in particular to a switching power supply, a self-powered circuit based on continuous conduction mode (CCM) and a self-powered circuit based on discontinuous conduction mode (DCM).

### BACKGROUND

With the diversification of electronic devices, power supply technology has achieved unprecedented development. The switching speed is getting faster and faster, the power is getting bigger and bigger, but the chip area is getting smaller and smaller. This puts higher requirements on the development indicators of switching power supply control technology.

As a type of power conversion equipment, the flyback switching power supply controls the switch transistor to turn on and off by the switching power supply chip, so as to achieve the energy conversion output of the switch. The switching power supply chip itself also consumes energy, so it is necessary to power the switching power supply chip. The existing flyback switching power supply provides the working voltage for the switching power supply chip by setting a rechargeable capacitor, and the rechargeable capacitor is charged by the auxiliary coil (feedback circuit). However, due to the coupling relationship between the coils of the transformer, the supply voltage will be affected by the output voltage. That is, when the load is heavy, the feedback supply voltage is high, and when it is light or no-load, the feedback supply voltage will drop much more than when it is heavy, and even lower than the voltage required for the normal operation of the switching power supply chip, thereby affecting the normal operation of the switching power supply.

### SUMMARY

In order to improve the stability of the operating voltage of a switching power supply, the present application provides a switching power supply and a self-powered circuit based on continuous conduction mode (CCM) and a self-powered circuit based on discontinuous conduction mode (DCM).

According to a first aspect, the present application provides self-powered circuit based on discontinuous conduction mode (DCM), applied to a flyback switching power supply, including:
a voltage-resistant switching transistor;
a charging branch; and
a charging control unit,
the voltage-resistant switching transistor is connected in series between a primary coil and the charging branch, and is configured to obtain a power supply voltage of the primary coil and output a charging voltage for charging the charging branch;
the voltage-resistant switching transistor adopts a depletion gallium nitride transistor, a drain of the voltage-resistant switching transistor is connected to the primary coil, a source of the voltage-resistant switching transistor is connected to the charging branch and the charging control unit, and a gate of the voltage-resistant switching transistor is grounded;
the charging branch includes a charging capacitor for supplying power to a switching power supply chip and a charging switching transistor for controlling whether the charging capacitor is charged, the charging switching transistor is connected between the charging capacitor and the voltage-resistant switching transistor;
the charging control unit is configured to control whether the charging branch is turned on; and
the charging control unit further includes a control transistor connected between the voltage-resistant switching transistor and the ground, and the control transistor is provided in parallel with the charging switching transistor and the charging capacitor, and the control transistor is configured to control whether a source of the voltage-resistant switching transistor is grounded.

By adopting the above technical solution, the high-voltage resistance performance of the voltage-resistant switching transistor enables the charging branch to be connected to the primary coil, so that the charging branch can draw power from the primary coil, thereby reducing the voltage instability caused by the coupling relationship between the coils. The switching power supply operates in a discontinuous conduction mode, and when the charging capacitor draws power from the primary coil, the charging current of the charging capacitor can be charged from 0, thereby reducing the area of the self-powered circuit. At the same time, the charging control unit is configured to control whether the charging branch is turned on, so as to ensure that the charging capacitor can meet the charging requirements and will not affect the normal energy storage of the primary coil.

In an embodiment, the charging branch further includes a protection resistor and a unidirectional conducting transistor connected in series with the charging switching transistor and the charging capacitor;

the protection resistor is configured to limit a charging current of the charging capacitor to protect the charging capacitor; and

the unidirectional conducting transistor is configured to make current of the charging branch unidirectionally conducted.

By adopting the above technical solution, a protection resistor is provided to prevent the charging branch from short-circuiting. At the same time, the protection resistor can better ensure that the charging capacitor is charged with a small voltage through voltage division, and a unidirectional conducting transistor is provided to prevent the charging capacitor from discharging in reverse.

In an embodiment, the charging control unit further includes a delay, the delay is connected between the control transistor and the switching power supply chip and is configured to delay an output of a control signal output by the switching power supply chip.

By adopting the above technical solution, the delay cooperates with the control transistor, and the control transistor is connected in series between the voltage-resistant switching transistor and the ground. When the control transistor is turned on, one end of the voltage-resistant switching transistor connected to the control transistor is grounded, so that the charging branch is disconnected, so that the self-powered circuit charges the charging capacitor while taking into account the high-voltage start-up operation of the switching power supply; within the delay duration of the delay, the charging branch is turned on and the charging capacitor is charged. When the delay duration of the delay is reached, the delay sends the control signal output by the switching power supply chip to the control transistor to turn on the control transistor. At this time, the charging branch is disconnected and the primary coil stores energy.

In an embodiment, the charging control unit further includes:
a current sampler; and
a comparison controller,
the current sampler is connected in series to the charging branch, and is configured to detect a charging current of the charging branch and output a sampling signal proportional to the charging current; and
an input end of the comparison controller is connected to the current sampler and the switching power supply chip, and the comparison controller is configured to receive the sampling signal and a control signal, and an output end of the comparison controller is connected to a control electrode of the control transistor, and the comparison controller is configured to control the control transistor to be turned on or off according to the sampling signal and the control signal.

By adopting the above technical solution, the control transistor is connected in series between the voltage-resistant switching transistor and the ground. When the control transistor is turned on, one end of the voltage-resistant switching transistor connected to the control transistor is grounded, so that the charging branch is disconnected, so that the self-powered circuit can charge the charging capacitor while taking into account the high-voltage start-up operation of the switching power supply. The charging current of the charging branch increases with the increase of the charging time, and the charging current of the charging branch is detected by setting a current sampler, and the comparison controller controls whether the control transistor is turned on according to the sampling signal and the control signal, so that the charging control unit controls the charging branch to be disconnected when the charging current of the charging capacitor is greater than the preset value, thereby ensuring that the charging capacitor is charged with a small current.

In an embodiment, the comparison controller includes a current comparator and an AND logic;

one input end of the current comparator is configured to obtain a preset current value, and another input end of the current comparator is connected to the current sampler, and the current comparator is configured to compare whether the charging current of the charging branch exceeds the preset current value, and output a comparison signal; and

one input end of the AND logic is connected to the switching power supply chip for obtaining the control signal, and the other input end is connected to the current comparator for obtaining the comparison signal; and an output end of the AND logic is connected to the control electrode of the control transistor for controlling whether the control transistor is turned on.

By adopting the above technical solution, the comparison controller compares the charging current with the preset current value, and the AND logic integrates the comparison signal with the control signal, and controls the control transistor to be turned on when the charging current exceeds the preset current value and the switching power supply chip outputs a high-level signal.

In an embodiment, the comparison controller further includes a trigger, the trigger is provided between the current comparator and the AND logic;

one input end of the trigger is connected to the current comparator, and the other input end of the trigger is connected to the switching power supply chip for obtaining the comparison signal and the control signal, and an output end of the trigger connected to the AND logic for outputting a trigger signal according to the comparison signal and the control signal; and

a NOT logic is connected between the trigger and the switching power supply chip.

By adopting the above technical solution, the trigger logic of the trigger is configured to prevent the situation where the charging current is lower than the preset current value after the charging branch is disconnected, causing the control transistor to be cut off again, and the charging branch is turned on again. The trigger is connected to the switching power supply chip, so that the trigger is controlled by the switching power supply chip to ensure that the signal output by the trigger remains unchanged after the trigger is triggered during the switching cycle.

In an embodiment, the charging control unit further includes:
a voltage sampler; and
a second AND logic;
an input end of the voltage sampler is connected to one end of the charging capacitor, and the voltage sampler is configured to obtain a voltage signal of the charging capacitor and output a judgment signal; an output end of the voltage sampler is connected to a control electrode of the control transistor, and the voltage sampler is configured to control the control transistor to be turned on or off;
the voltage sampler is preset with a high voltage reference value, and in response to that the charging capacitor voltage signal is greater than the high voltage reference value, the voltage sampler controls the control transistor to be turned on; and
an input end of the second AND logic is connected to the voltage sampler and the switching power supply chip, and the second AND logic is configured to receive the judgment signal and the control signal, and an output end of the second AND logic is connected to the control electrode of the control transistor, and the second AND logic is configured to control the control transistor to be turned on or off according to the judgment signal and the control signal.

By adopting the above technical solution, the control transistor is connected in series between the voltage-resistant switching transistor and the ground. When the control transistor is turned on, one end of the voltage-resistant switching transistor connected to the control transistor is grounded, so that the charging branch is disconnected, so that the self-powered circuit charges the charging capacitor while taking into account the high-voltage start-up operation of the switching power supply. As the charging time increases, the charging capacitor is continuously charged, and its voltage value continues to increase. By setting a voltage sampler to detect the voltage value of the charging capacitor and output a judgment signal, when the voltage signal exceeds the high voltage reference value, it indicates that the charging capacitor is fully charged, and the second AND logic obtains the judgment signal and the control signal. When the voltage signal and the control signal of charging capacitor meet the requirements, the voltage sampler controls the control transistor to be turned on, thereby disconnecting the charging branch.

In an embodiment, the voltage sampler includes a voltage comparator, a low voltage reference circuit and a high voltage reference circuit provided at an input end of the voltage comparator, the low voltage reference circuit is configured to provide a low voltage reference value, the high voltage reference circuit is configured to provide a high voltage reference value, and the high voltage reference value is greater than the low voltage reference value; and

a first conductive element is provided between an output end of the voltage comparator and the low voltage reference circuit, and a second conductive element is provided between the output end of the voltage comparator and the high voltage reference circuit, and the first conductive element and the second conductive element have opposite conduction conditions.

By adopting the above technical solution, a low voltage reference circuit is provided, and the low voltage reference circuit provides a low voltage reference value. When the charging voltage of the charging capacitor is less than the low voltage reference, it means that the charging capacitor needs to be recharged. The high voltage reference circuit provides a high voltage reference value, so that the charging capacitor can be compared with different reference values under different states. At the same time, the conduction conditions of the first conductive element and the second conductive element are provided to be opposite, so as to prevent the low voltage reference circuit and the high voltage reference circuit from being connected to the voltage comparator at the same time.

In an embodiment, the charging control unit further includes a first AND logic, an input end of the first AND logic is connected to the voltage sampler, another input end of the first AND logic is connected to the switching power supply chip, and an output end of the first AND logic is connected to a control electrode of the charging switching transistor.

By adopting the above technical solution, the first AND logic controls whether the charging switching transistor is turned on according to the judgment signal and the control signal of the switching power supply chip, so that the charging switching transistor can only be turned on when the power and the control signal of the charging capacitor meet the requirements at the same time, so as to prevent the charging switching transistor from being turned on when the charging capacitor power is sufficient.

In an embodiment, the charging control unit further includes a delay and an OR logic;

the delay is preset with a preset duration, and an input end of the delay is connected to the switching power supply chip, and the delay is configured to delay an output of a control signal output by the switching power supply chip; and

an input end of the OR logic is connected to the second AND logic and the delay respectively, and an output end of the OR logic is connected to the control electrode of the control transistor for controlling the control transistor to be turned on or off.

By adopting the above technical solution, through the cooperation of the delay and the OR logic, it is possible to prevent the voltage signal of the charging capacitor from failing to reach the high voltage reference value and affecting the energy storage of the primary coil. By utilizing the conduction characteristics of the OR logic, the control transistor can be turned on when either the charging time reaches the preset duration or the voltage signal of the charging capacitor reaches the high voltage reference value.

According to a second aspect, the present application provides a self-powered circuit based on continuous conduction mode (CCM), applied to a flyback switching power supply, including:
a voltage-resistant switching transistor;
a charging branch;
a mode switching unit; and
a charging control unit,
the voltage-resistant switching transistor is connected between a primary coil and the charging branch, and is configured to obtain a power supply voltage of the primary coil and output a charging voltage for charging the charging branch;
the voltage-resistant switching transistor adopts a depletion gallium nitride transistor, a drain of the voltage-resistant switching transistor is connected to the primary coil, a source of the voltage-resistant switching transistor is connected to the charging branch and the charging control unit, and a gate of the voltage-resistant switching transistor is grounded;
the charging branch includes a charging capacitor for supplying power to a switching power supply chip and a charging switching transistor for controlling whether the charging capacitor is charged, the charging switching transistor is connected between the charging capacitor and the voltage-resistant switching transistor;
the mode switching unit is configured to monitor the voltage of the charging capacitor and the voltage of an auxiliary coil, and output a switching signal for adjusting the output of the control signal of the switching power supply chip;
the charging control unit is configured to control whether the charging branch is turned on; and
the charging control unit includes a control transistor connected between the voltage-resistant switching transistor and the ground, and the control transistor is provided in parallel with the charging switching transistor and the charging capacitor, and the control transistor is configured to control whether a source of the voltage-resistant switching transistor is grounded.

By adopting the above technical solution, the high-voltage resistance performance of the voltage-resistant switching transistor enables the charging branch to be connected to the primary coil, so that the charging branch can draw power from the primary coil, thereby reducing the voltage instability caused by the coupling relationship between the coils. The switching power supply operates in a continuous conduction mode, and when the charging capacitor draws power from the primary coil, in order to ensure that the charging capacitor is charged with a small current, when the charging capacitor needs to be charged, the mode switching unit adjusts the control signal so that the secondary coil can be fully discharged, the charging current of the charging capacitor can be charged from 0, thereby reducing the area of the self-powered circuit. At the same time, the charging control unit is configured to control whether the charging branch is turned on, so as to ensure that the charging capacitor can meet the charging requirements and will not affect the normal energy storage of the primary coil.

In an embodiment, the charging branch further includes a protection resistor and a unidirectional conducting transistor connected in series with the charging switching transistor and the charging capacitor;

the protection resistor is configured to limit a charging current of the charging capacitor to protect the charging capacitor; and

the unidirectional conducting transistor is configured to make current of the charging branch unidirectionally conducted.

By adopting the above technical solution, a protection resistor is provided to prevent the charging branch from short-circuiting. At the same time, the protection resistor can better ensure that the charging capacitor is charged with a small voltage through voltage division, and a unidirectional conducting transistor is provided to prevent the charging capacitor from discharging in reverse.

In an embodiment, the mode switching unit includes a voltage sampler and a sampling feedback device;

the voltage sampler is preset with a low voltage reference value, and the voltage sampler is configured to obtain a voltage signal of the charging capacitor, compare the voltage signal with the low voltage reference value, and output a judgment signal; and

the voltage sampling feedback device is provided between the auxiliary coil and the switching power supply chip, and samples a voltage on the auxiliary coil to obtain a sampling signal, the switching power supply chip is configured to control whether it is necessary to prolong duration of the control signal being at a low level according to the sampling signal and the judgment signal to convert the switching power supply from a continuous conduction mode to a discontinuous conduction mode.

By adopting the above technical solution, by setting a low voltage reference value, the voltage signal of the charging capacitor is judged against the low voltage reference value to determine whether the charging capacitor needs to be recharged. When the charging capacitor needs to be recharged, the switching power supply chip obtains the judgment signal to prolongs the duration of the control signal being at a low level, so that the secondary coil is fully discharged, and the switching power supply is converted from a continuous conduction mode to a discontinuous conduction mode; the voltage of the auxiliary coil is sampled by a voltage sampling feedback device, and whether the secondary coil is fully discharged is determined based on the coupling relationship between the coils. When the secondary coil is fully discharged, a sampling signal is output to enable the switching power supply chip to output a high-level signal.

In an embodiment, the voltage sampler includes a voltage comparator, a low voltage reference circuit and a high voltage reference circuit provided at an input end of the voltage comparator;

the low voltage reference circuit is configured to provide a low voltage reference value, the high voltage reference circuit is configured to provide a high voltage reference value, and the high voltage reference value is greater than the low voltage reference value;

a first conductive element is provided between an output end of the voltage comparator and the low voltage reference circuit, and a second conductive element is provided between the output end of the voltage comparator and the high voltage reference circuit, and the first conductive element and the second conductive element have opposite conduction conditions.

By adopting the above technical solution, a high voltage reference circuit is provided to limit the amount of electricity of the charging capacitor. When the voltage signal is greater than the high voltage reference value, it indicates that the charging capacitor has been recharged. By setting a high voltage reference circuit and a low voltage reference circuit, the charging capacitor can be compared with different reference values under different states. At the same time, the conduction conditions of the first conductive element and the second conductive element are provided to be opposite to prevent the low voltage reference circuit and the high voltage reference circuit from being connected to the voltage comparator at the same time.

In an embodiment, a first AND logic is provided between the voltage comparator and the charging switching transistor, an input end of the first AND logic is respectively connected to the voltage comparator and the switching power supply chip, and an output end of the first AND logic is connected to a control electrode of the charging switching transistor.

By adopting the above technical solution, the first AND logic controls whether the charging switching transistor is turned on according to the judgment signal and the control signal of the switching power supply chip, so that the charging switching transistor can only be turned on when the power and the control signal of the charging capacitor meet the requirements at the same time, so as to prevent the charging switching transistor from being turned on when the charging capacitor power is sufficient.

In an embodiment, the charging control unit further includes:
a delay;
a second AND logic; and
an OR logic,
the delay is connected between a control transistor and the switching power supply chip, and is configured to delay an output of a control signal output by the switching power supply chip;
an input end of the second AND logic is connected to the voltage sampler and the switching power supply chip, and an output end of the second AND logic is coupled to the control transistor, the second AND logic is configured to receive the judgment signal and the control signal, and output a voltage identification signal to the control transistor according to the judgment signal and the control signal; and
an input end of the OR logic is respectively connected to an output end of the delay and an output end of the second AND logic, the OR logic is configured to obtain a control signal and a voltage identification signal delayed by the delay, an output end of the OR logic is connected to a control electrode of the control transistor, and the OR logic is configured to control the control transistor to be turned on or off.

By adopting the above technical solution, whether the control transistor is turned on is related to the voltage signal of the charging capacitor and the switching power supply chip through the second AND logic. When the voltage signal of the charging capacitor and the switching power supply chip meet the requirements, the second AND logic outputs a high-level signal. By setting the delay and the OR logic in coordination, it can prevent the voltage signal of the charging capacitor from failing to reach the high voltage reference value and affecting the energy storage of the primary coil. At the same time, it can effectively prevent the control transistor from being turned on and, in the case of energy storage in the primary coil, the voltage signal of the charging capacitor is again less than the high voltage reference value due to the charging capacitor supplying power to the switching power supply chip, causing the control transistor to be cut off again.

In an embodiment, the charging control unit further includes:
a current sampler;
a comparison controller;
a second AND logic; and
an OR logic,
the current sampler is connected in series to the charging branch, and is configured to detect a charging current of the charging branch and output a sampling signal proportional to the charging current;
an input end of the comparison controller is connected to the current sampler and the switching power supply chip, the comparison controller is configured to receive the sampling signal and the control signal, and output a current identification signal according to the sampling signal and the control signal; and
an input end of the second AND logic is connected to the voltage sampler and the switching power supply chip, an output end of the second AND logic is coupled to the control transistor, the second AND logic is configured to receive the judgment signal and the control signal, and output a voltage identification signal to the control transistor according to the judgment signal and the control signal;
an input end of the OR logic is respectively connected to an output end of the comparison controller and the output end of the second AND logic, the OR logic is configured to obtain the current identification signal and a voltage identification signal, an output end of the OR logic is connected to a control electrode of the control transistor, and the OR logic is configured to control the control transistor to be turned on or off.

By adopting the above technical solution, the second AND logic makes whether the control transistor is turned on related to the voltage signal of the charging capacitor and the switching power supply chip. When the voltage signal of the charging capacitor and the switching power supply chip meet the requirements, the second AND logic outputs a high-level signal. As the charging branch is turned on, the charging current continues to increase, and the amount of the charging capacitor also continues to increase. In order to ensure that the charging capacitor is charged with a small current, the charging current is collected by setting a current sampler, and the charging current is compared with the preset current value through a comparison controller to determine whether the charging current is greater than the preset current value. Under the action of the OR logic, when either the second AND logic or the comparison controller outputs a high-level signal, the OR logic outputs a high-level signal, thereby preventing the voltage signal of the charging capacitor from failing to reach the high-voltage reference value and affecting the energy storage of the primary coil.

In an embodiment, the comparison controller includes a current comparator and a trigger;

one input end of the current comparator obtains a preset current value, and the other input end of the current comparator is connected to the current sampler, and the current comparator is configured to compare whether the charging current of the charging branch exceeds the preset current value, and output a comparison signal; and

one input end of the trigger is connected to the switching power supply chip for obtaining the control signal, and the other input end of the trigger is connected to an output end of the current comparator for obtaining the comparison signal, and an output end of the trigger is connected to the OR logic.

By adopting the above technical solution, the trigger logic of the trigger is used to prevent the charging branch from being disconnected and controlled by the comparison controller That is, when the voltage of the charging capacitor does not reach the high voltage reference value, the charging current is greater than the preset current value and the charging branch is disconnected. After the charging branch is disconnected, the charging current is lower than the preset current value and the control transistor is cut off again, and the charging branch is turned on again. The trigger is connected to the switching power supply chip, so that the trigger is controlled by the switching power supply chip to ensure that the signal output by the trigger remains unchanged after the trigger is triggered during the switching cycle.

According to a third aspect, the present application provides a method for self-powering a switching power supply of the self-powered circuit based on DCM, including:
obtaining a control signal of the switching power supply chip;
determining whether the control signal is at a high level;
in response to that the control signal is at the high level, determining whether the charging branch is turned on;
in response to that the charging branch is turned on, charging the charging capacitor,
in response to that the charging branch is turned off, controlling the primary coil to store energy; or
in response to that the control signal is not at the high level, reobtaining the control signal.

In an embodiment, the determining whether the charging branch is turned on includes:
determining whether turn-on duration of the charging branch reaches a preset duration;
in response to that the turn-on duration of the charging branch does not reach the preset duration, turning on the charging branch; or
in response to that the turn-on duration of the charging branch reaches the preset duration, turning off the charging branch.

In an embodiment, the determining whether the charging branch is turned on includes:
determining whether the charging current of the charging branch is greater than the preset current value;
in response to that the charging current of the charging branch is not greater than the preset current value, turning on the charging branch; or
in response to that the charging current of the charging branch is greater than the preset current value, turning off the charging branch.

In an embodiment, before the determining whether the charging branch is turned on, the method further includes:
in response to a determination that the voltage signal of the charging capacitor is less than the low voltage reference value, determining whether the voltage signal of the charging capacitor is less than the high voltage reference value;
in response to that the voltage signal of the charging capacitor is less than the low voltage reference value, turning on the charging branch;
in response to that the voltage signal of the charging capacitor is not less than the low voltage reference value, turning off the charging branch; and
before the determining whether the charging branch is turned on, the method further includes:
in response to determining that the voltage signal of the charging capacitor is less than the low voltage reference value, determining whether the voltage signal of the charging capacitor is less than the high voltage reference value, and whether turn-on duration of the charging branch reaches a preset duration;
in response to that the voltage signal of the charging capacitor is not less than the high voltage reference value and the turn-on duration of the charging branch does not reach the preset duration, turning on the charging branch;
in response to that the voltage signal of the charging capacitor is less than the high voltage reference value and/or the turn-on duration of the charging branch reaches the preset duration, turning off the charging branch.

According to a fourth aspect, the present application provides a method for self-powering a switching power supply of the self-powered circuit based on CCM, including:
obtaining the voltage signal of the charging capacitor, and determining whether the charging capacitor needs to be recharged according to the voltage signal;
in response to that the charging capacitor needs to be recharged, prolonging, by the switching power supply chip, a duration of the control signal being at a low level;
obtaining the sampling signal of the auxiliary coil, and determining whether a secondary coil is fully discharged according to the sampling signal; in response to that the secondary coil is fully discharged, switching and outputting the control signal from low level to high level; determining whether the charging branch is turned on; in response to that the charging branch is turned on, charging the charging capacitor, and in response to that the charging branch is not turned on, controlling the primary coil to store energy; and in response to that the secondary coil is not fully discharged, continuing to prolong the duration of the control signal being at the low level; or
in response to that the charging capacitor does not need to be recharged, continuing to obtain the voltage signal.

In an embodiment, the determining whether the charging branch is turned on includes:
determining whether the voltage signal of the charging capacitor is less than the high voltage reference value;
determining whether turn-on duration of the charging branch reaches the preset duration;
in response to that the voltage signal of the charging capacitor is not less than the high voltage reference value and the turn-on duration of the charging branch does not reach the preset duration, turning on the charging branch; or
in response to that the voltage signal of the charging capacitor is less than the high voltage reference value and/or the turn-on duration of the charging branch reaches the preset duration, turning off the charging branch is turned off.

In an embodiment, the determining whether the charging branch is turned on includes:
determining whether the voltage signal of the charging capacitor is less than the high voltage reference value;
determining whether the charging current of the charging branch is greater than the preset current value;
in response to that the voltage signal of the charging capacitor is not less than the high voltage reference value and the charging current of the charging branch is not greater than the preset current value, turning on the charging branch; or
in response to that the voltage signal of the charging capacitor is less than the high voltage reference value and/or the charging current of the charging branch is greater than the preset current value, turning off the charging branch.

According to a fifth aspect, the present application provides a switching power supply of the self-powered circuit based on DCM, including:
a transformer;
an output control module configured to improve load regulation; and
the self-powered circuit configured to supply power to the output control module;
the transformer includes the primary coil, a secondary coil and an auxiliary coil;
the output control module includes the switching power supply chip configured to output the control signal;
the self-powered circuit includes the voltage-resistant switching transistor, the charging branch and the charging control unit; and
the voltage-resistant switching transistor is connected between the charging branch and the primary coil, the charging branch is connected in series with the voltage-resistant switching transistor, and the charging control unit is coupled between the output control module and the primary coil.

According to a sixth aspect, the present application provides a switching power supply of the self-powered circuit based on CCM, including:
a transformer;
an output control module configured to improve load regulation; and
a self-powered circuit configured to supply power to the output control module;
the transformer includes the primary coil, a secondary coil and the auxiliary coil;
the output control module includes the switching power supply chip configured to output the control signal;
the self-powered circuit includes the voltage-resistant switching transistor, the charging branch, the mode switching unit and the charging control unit; and
the voltage-resistant switching transistor is connected between the charging branch and the primary coil, the charging branch is connected in series with the voltage-resistant switching transistor, the mode switching unit is coupled between the charging branch and the auxiliary coil, and the charging control unit is coupled between the mode switching unit and the primary coil.

In summary, the present application includes at least one of the following beneficial technical effects.

Firstly, by setting a voltage-resistant switching transistor to connect the charging branch with the primary coil in series, the charging capacitor does not need to be powered by the auxiliary coil, and can be powered from the primary coil adaptively during the switching cycle, thereby improving the stability of the charging capacitor voltage supply.

Secondly, by setting a charging control unit, the self-powered circuit can not only realize the adaptive power replenishment of the charging capacitor but also take into account the high-voltage startup function at the same time, thereby improving the self-power supply efficiency

Thirdly, by setting the preset duration of the delay to set the longest adaptive power replenishment time, the normal operation of the switching power supply is ensured.

Fourthly, by setting a current sampler and a comparison controller, the charging current of the charging capacitor is monitored, and the power replenishment is adaptively adjusted according to the charging current.

Lastly, by setting a voltage sampler, the voltage of the charging capacitor is monitored, and the power replenishment is adaptively adjusted according to the voltage of the charging capacitor.

### BRIEF DESCRIPTION OF THE DRAWINGS

FIG. 1 is a structural schematic diagram of a partial circuit of a switching power supply according to an embodiment of the present application.

FIG. 2 is a structural schematic diagram of a self-powered circuit based on discontinuous conduction mode (DCM) according to an embodiment of the present application.

FIG. 3 is a waveform diagram when a charging control unit of the self-powered circuit based on DCM is a delay control unit according to an embodiment of the present application.

FIG. 4 is a structural schematic diagram of the self-powered circuit based on DCM according to another embodiment of the present application.

FIG. 5 is a waveform diagram when the charging control unit of the self-powered circuit based on DCM is a current sampling control unit according to an embodiment of the present application.

FIG. 6 is a structural schematic diagram of a self-powered circuit based on DCM according to yet another embodiment of the application.

FIG. 7 is a waveform diagram when the charging control unit of the self-powered circuit based on DCM is a voltage sampling control unit according to an embodiment of the present application.

FIG. 8 is a structural schematic diagram of a self-powered circuit based on continuous conduction mode (CCM) according to an embodiment of the present application.

FIG. 9 is a structural schematic diagram of the self-powered circuit based on CCM according to another embodiment of the present application.

FIG. 10 is a structural schematic diagram of the self-powered circuit based on CCM according to yet another embodiment of the present application.

FIG. 11 is a waveform diagram when a charging control unit of the self-powered circuit based on CCM is a delay control unit according to an embodiment of the present application.

FIG. 12 is a structural schematic diagram of a circuit structure of a self-powered circuit based on CCM according to yet another embodiment of the present application.

FIG. 13 is a waveform diagram when the charging control unit of the self-powered circuit based on CCM is a current sampling control unit according to an embodiment of the present application.

FIG. 14 is a flowchart of a method for self-powering a switching power supply of a self-powered circuit based on DCM according to an embodiment of the present application.

FIG. 15 is a flowchart of the method for self-powering a switching power supply of a self-powered circuit based on DCM according to another embodiment of the present application.

FIG. 16 is a flowchart of the method for self-powering a switching power supply of a self-powered circuit based on DCM according to yet another embodiment of the present application.

FIG. 17 is a flowchart of the method for self-powering a switching power supply of a self-powered circuit based on DCM according to yet another embodiment of the present application.

FIG. 18 is a flowchart of the method for self-powering a switching power supply of a self-powered circuit based on DCM according to yet another embodiment of the present application.

FIG. 19 is a flowchart of method for self-powering a switching power supply of a self-powered circuit based on CCM according to an embodiment of the present application.

FIG. 20 is a flowchart of the method for self-powering a switching power supply of a self-powered circuit based on CCM according to another embodiment of the present application.

FIG. 21 is a flowchart of the method for self-powering a switching power supply of a self-powered circuit based on CCM according to yet another embodiment of the present application.

### DETAILED DESCRIPTION OF THE EMBODIMENTS

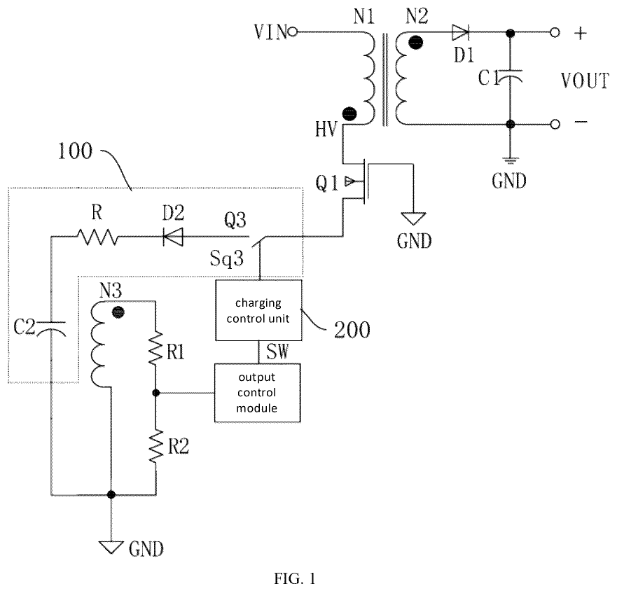

The present application is further described in detail below in conjunction with the accompanying drawings FIG. 1 to FIG. 21.

The working modes of switching power supplies are usually divided into continuous conduction mode (CCM) and discontinuous conduction mode (DCM). The discontinuous conduction mode is also called intermittent mode. The difference between the two working modes lies in whether the current flowing in the coil is reduced to 0 in each switching cycle. For the DCM, the current flowing in the coil is reduced to 0 in each switching cycle, so when each new switching cycle comes, the current flowing in the coil starts to rise from 0. For the CCM, the current flowing in the coil has not yet decreased to 0 in each switching cycle, and the next switching cycle comes, so when each new switching cycle comes, the current flowing in the coil starts to rise from a certain value (non-zero value).

The mode of the switching power supply is determined by the load to which it is connected. When the switching power supply is lightly loaded or unloaded, the output power requirement is not high and it works in discontinuous conduction mode. When the switching power supply is heavily loaded or has a high output power, a higher operating frequency is required, and the switching power supply needs to work in continuous conduction mode. When designing a switching power supply, it is necessary to design the switching power supply to work only in discontinuous conduction mode or to switch between continuous conduction mode and discontinuous conduction mode according to the load according to the use requirements.

The embodiment of the present application discloses a switching power supply. As shown in FIG. 1, the switching power supply includes a transformer, an output control module for improving the load regulation rate, and a self-powered circuit for powering the output control module. The transformer includes a primary coil N1, an auxiliary coil N3, a secondary coil N2, and an output capacitor C1 connected in parallel to both ends of the secondary coil N2. The two ends of the output capacitor C1 are configured to connect the load. An output unidirectional tube D1 is also provided between the secondary coil N2 and the charging capacitor C2. The output unidirectional tube D1 is a diode, and its anode is connected to the secondary coil N2, and its cathode is connected to the output capacitor C1 to prevent the output capacitor C1 from discharging the secondary coil N2. The primary coil N1 and the secondary coil N2 are mutually coupled and induced, when the primary coil N1 is turned on, the primary coil N1 stores energy, the secondary coil N2 does not work, and the output capacitor C1 supplies power to the load. One end of the primary coil N1 is configured to receive the power supply voltage VIN after rectification by the rectifier, and the other end of the primary coil N1 is connected to the self-powered circuit. When the primary coil N1 is turned on, the self-powered circuit draws power from the primary coil N1. The output control module includes a switching power supply chip PWM and its peripheral circuits. The switching power supply chip PWM outputs a control signal SW for controlling the self-powered circuit to charge during the switching cycle of the switching power supply, and the control signal SW output by the switching power supply chip PWM is also configured to adjust the output voltage VOUT of the switching power supply. In the embodiment of the present application, the control signal SW is a pulse width modulation (PWM) waveform signal.

The embodiment of the present application discloses a self-powered circuit of the switching power supply based on DCM. As shown in FIG. 1, the self-powered circuit includes a voltage-resistant switching transistor Q1, a charging branch 100 and a charging control unit 200, the charging branch 100 includes a charging capacitor C2, a charging switching transistor Q3 and a protection resistor R.

The voltage-resistant switching transistor Q1 is connected between the primary coil N1 and the charging capacitor C2, and the voltage-resistant switching transistor Q1 is configured to obtain the power supply voltage of the primary coil N1, and output the charging voltage for charging the charging capacitor C2.

The charging capacitor C2 draws power from the primary coil N1 and supplies power to the switching power supply chip PWM.

The charging switching transistor Q3 is connected between the charging capacitor C2 and the voltage-resistant switching transistor Q1. The charging switching transistor Q3 is configured to control whether to charge the charging capacitor C2 when the voltage-resistant switching transistor Q1 is turned on and outputs the charging voltage.

The protection resistor R is connected in series between the charging switching transistor Q3 and the charging capacitor C2, and is configured to limit the charging current I of the charging capacitor C2 to protect the charging capacitor C2.

The charging control unit 200 is configured to control whether the charging branch 100 is turned on.

The primary coil N1, the voltage-resistant switching transistor Q1 and the charging branch 100 constitute a charging circuit for charging the charging capacitor C2. When the control signal SW output by the switching power supply chip PWM is at a high level, if the charging control unit 200 controls the charging branch 100 to be turned on, the charging circuit is turned on and the charging capacitor C2 starts to charge. If the charging control unit 200 controls the charging branch 100 to be turned off, the charging circuit is disconnected and the charging capacitor C2 stops charging.

The control electrode of the charging switching transistor Q3 is connected to the switching power supply chip PWM and is controlled by the control signal SW output by the switching power supply chip PWM. When the control signal SW output by the switching power supply chip PWM is at a high level, the charging switching transistor Q3 is turned on. The charging switching transistor Q3 is not limited to a Metal-Oxide-Semiconductor Field-Effect Transistor (MOSFET), triode and other switching transistor.

In the embodiment of the present application, the voltage-resistant switching transistor Q1 adopts a depletion gallium nitride transistor. Since the area of the device is related to the resistant voltage and the current flowing through the device, the higher the resistant voltage and the greater the current flowing through the device, the corresponding area of the device will also increase. The gallium nitride transistor is used as a high-voltage switching transistor and uses its working characteristics to take power from the source end to ensure that the chip only works in a low-voltage state, so as to meet the high resistant voltage requirements of the device, reduce the complexity of the device, and thus reduce the final device area. At the same time, when the switching power supply works in the discontinuous conduction mode, the coil energy is completely discharged, and the current flowing in the coil is reduced to 0 in each switching cycle. Therefore, when each new switching cycle arrives, the current flowing in the coil starts to rise from 0. That is, each time the control signal SW output by the switching power supply chip PWM is high, the switching power supply chip PWM first charges the charging capacitor C2 with the minimum current through the source of the voltage-resistant switching transistor Q1 to reduce the area of the self-powered circuit.

The drain of the voltage-resistant switching transistor Q1 is connected to the primary coil N1, the gate of the voltage-resistant switching transistor Q1 is grounded, and the charging control unit 200 is connected in series between the source of the voltage-resistant switching transistor Q1 and the ground. The charging control unit 200 is preset with a charging requirement and outputs a charging control signal Sq2, and the charging control signal Sq2 is configured to control whether the charging branch 100 that is turned on remains turned on. When the charging requirement is not met the charging control signal Sq2 controls the charging branch 100 to remain turned on, and when the charging requirement is met, the charging control signal Sq2 controls the charging branch 100 to be disconnected. In the embodiment of the present application, whether the charging branch 100 is turned on is determined by whether the source of the voltage-resistant switching transistor Q1 is grounded. Therefore, in order to prevent the charging capacitor C2 from discharging to the ground after charging is completed, the charging branch 100 also includes a unidirectional conducting transistor D2, which is configured to make the the current of the charging branch 100 unidirectional conducted. When the current flows from the charging switching transistor Q3 to the charging capacitor C2, the unidirectional conducting transistor D2 is turned on. Otherwise, the unidirectional conducting transistor D2 is turned off. In the embodiment of the present application, the unidirectional conducting transistor D2 also adopts a diode, and the anode of the unidirectional conducting transistor D2 is connected to the charging switching transistor Q3, and the cathode of the unidirectional conducting transistor D2 is connected to the charging capacitor C2.

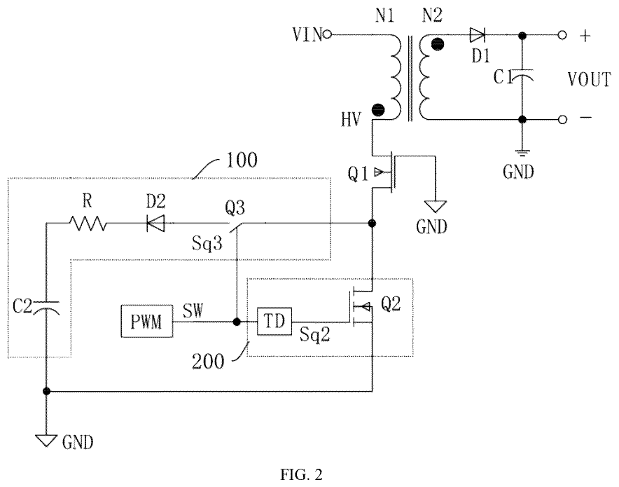

In an embodiment, as shown in FIG. 2, the charging control unit 200 is a delay control unit, which includes: a control transistor Q2 and a delay TD.

The control transistor Q2 is connected between the voltage-resistant switching transistor Q1 and the ground, and the control transistor Q2 is provided in parallel with the charging switching transistor Q3 and the charging capacitor C2. The control transistor Q2 is configured to control whether the source of the voltage-resistant switching transistor Q1 is grounded.

The delay TD is connected between the control transistor Q2 and the switching power supply chip PWM, and is used for delaying the output of the control signal SW output by the switching power supply chip PWM.

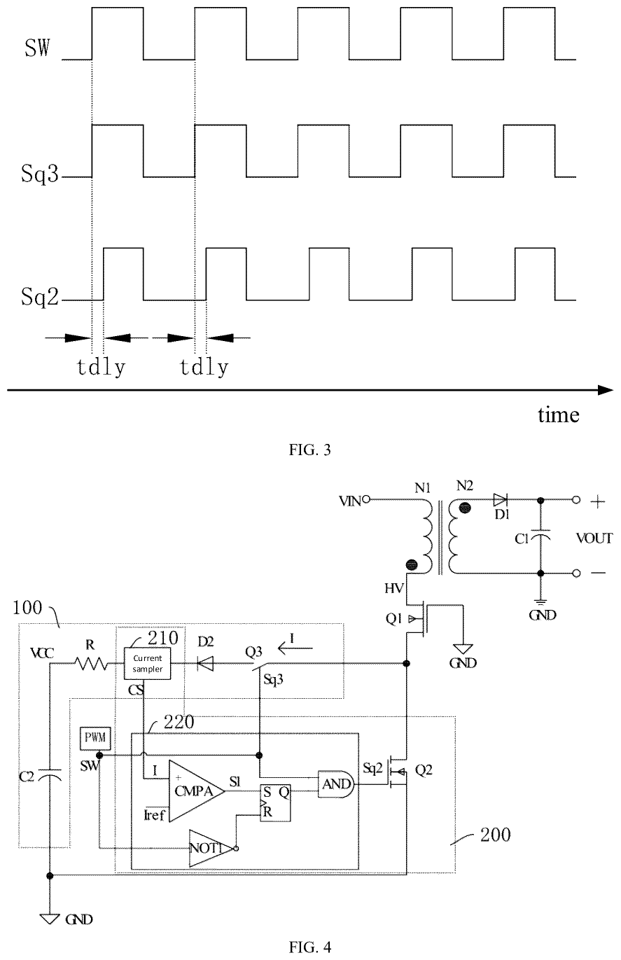

Specifically, as shown in FIG. 2 and FIG. 3, the primary coil N1, the voltage-resistant switching transistor Q1 and the control transistor Q2 constitute the primary circuit. When the control transistor Q2 is turned on, the primary circuit is turned on. The control signal SW output by the switching power supply chip PWM is also configured to control the charging switching transistor Q3 to be turned on or off. In order to ensure that the charging capacitor C2 has enough time to charge, the delay TD is provided with a preset duration tdly, and the preset duration tdly is a time in the order of hundreds of nanoseconds to ensure that the energy storage of the primary coil N1 of the switching power supply is not affected. The input end of the delay TD is connected to the switching power supply chip PWM, and the output end of the delay TD is connected to the control electrode of the control transistor Q2, which is configured to output a delay signal, and the delay signal is the control signal SW of the delayed output. In the embodiment of the present application, the charging requirement is a time requirement, and the delay signal is the charging control signal Sq2. The delay TD is triggered by a high level signal, that is, when the control signal SW is at a high level, the delay TD starts timing. When the preset duration tdly is not reached, the delay TD still maintains a low-level output. At this time, the charging requirement is not met, and the charging control signal Sq2 controls the charging branch 100 to continue to be turned on. When the timing duration reaches the preset duration tdly, the delay TD outputs a high level. At this time, the charging requirement is met, and the charging control signal Sq2 controls the charging branch 100 to be disconnected, that is, the control input of the control transistor Q2 is a high level signal. The control electrode of the control transistor Q2 is connected to the delay TD. The delay TD receives the control signal SW output by the switching power supply chip PWM and outputs it to the control transistor Q2 after delay. Therefore, the control transistor Q2 is still controlled by the control signal SW output by the switching power supply chip PWM. When the control transistor Q2 receives the control signal SW output by the switching power supply chip PWM and is at a high level, the control transistor Q2 and the primary circuit are turned on. The control transistor Q2 is not limited to a MOSFET, triode and other switching transistor

As shown in FIG. 2 and FIG. 3, when the charging circuit is turned on, the primary coil N1 is also storing energy, but the energy storage speed of the primary coil N1 is slow. At the same time, as the turn-on duration of the charging circuit is turned on gradually increases, the charging current I of the charging circuit gradually increases. To ensure that the switching power supply can work normally and that the charging capacitor C2 can meet the power consumption requirements of the switching power supply chip PWM, the preset duration tdly is set to the maximum while ensuring the normal operation of the switching power supply to ensure that the charging capacitor C2 has sufficient charging time.

As shown in FIG. 2 and FIG. 3, since the voltage-resistant switching transistor Q1 adopts a depletion gallium nitride transistor, it is in the on state under normal conditions. Therefore, when the control transistor Q2 is turned off and the charging switching transistor Q3 is turned on, the charging circuit is turned on and the charging capacitor C2 starts to charge. When the control transistor Q2 is turned on, the source of the voltage-resistant switching transistor Q1 is pulled down to ground, and the source voltage of the voltage-resistant switching transistor Q1 is close to 0V, so the source voltage of the voltage-resistant switching transistor Q1 is lower than the voltage of the charging capacitor C2, the charging circuit is disconnected, and the charging capacitor C2 stops charging. At this time, the primary circuit is turned on and the primary coil N1 stores energy. When the control transistor Q2 is turned on, the unidirectional conducting transistor D2 is reversely turned off, the charging branch 100 is turned off, and the charging capacitor C2 stops charging, and it will not discharge to the ground through the charging switching transistor Q3 and the control transistor Q2.

The self-powering principle of a self-powered circuit of a switching power supply based on a discontinuous conduction mode in an embodiment of the present application is as follows: when the switching power supply chip PWM outputs a high level signal, the charging switching transistor Q3 is turned on, and within the preset duration tdly, the delay TD maintains a low level output, that is, the control transistor Q2 is turned off, so that the charging circuit remains turned on and the charging capacitor C2 is charged. When the timing duration of the delay TD reaches the preset duration tdly, the delay TD outputs a high level signal, and the control transistor Q2 is turned on. At this time, although the charging switching transistor Q3 is also turned on, the source of the voltage-resistant switching transistor Q1 is grounded, so the charging capacitor C2 stops charging, and the primary circuit is turned on to ensure that the primary coil N1 can store energy normally. When the control signal SW output by the switching power supply chip PWM is low, the charging switching transistor Q3 and the control transistor Q2 are both turned off. At this time, the primary circuit is disconnected, and the secondary coil N2 supplies power to the load.

In an embodiment, as shown in FIG. 4, the charging control unit 200 is a current sampling control unit, which includes: a control transistor Q2, a current sampler 210, and a comparison controller 220.

The control transistor Q2 is connected between the voltage-resistant switching transistor Q1 and the ground, and the control transistor Q2 is provided in parallel with the charging switching transistor Q3 and the charging capacitor C2. The control transistor Q2 is configured to control whether the source of the voltage-resistant switching transistor Q1 is grounded.

The current sampler 210 is connected in series to the charging branch 100, and is configured to detect the charging current I of the charging branch 100, and output a sampling signal CS proportional to the charging current I.

The comparison controller 220 has an input end connected to the current sampler 210 and the switching power supply chip PWM, and the comparison controller 220 is configured to receive the sampling signal CS and the control signal SW. Its output end is connected to the control electrode of the control transistor Q2, and controls the control transistor Q2 to be turned on or off according to the sampling signal CS and the control signal SW.

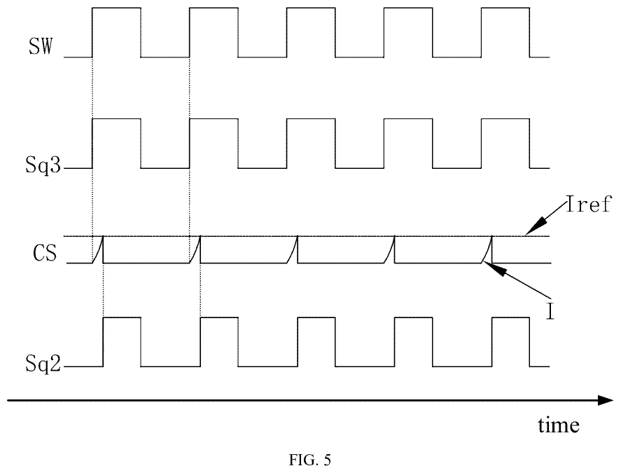

Specifically, as shown in FIG. 4 and FIG. 5, the primary coil N1, the voltage-resistant switching transistor Q1 and the control transistor Q2 constitute a primary circuit, and when the control transistor Q2 is turned on, the primary circuit is turned on. The control transistor Q2 is not limited to a switching transistor such as a MOSFET or a triode. The drain of the voltage-resistant switching transistor Q1 is connected to the primary coil N1, the gate of the voltage-resistant switching transistor Q1 is grounded, the source of the voltage-resistant switching transistor Q1 is connected to the drain of the control transistor Q2, and the source of the control transistor Q2 is grounded. Since the voltage-resistant switching transistor Q1 adopts a depletion gallium nitride transistor, it is in the on state under normal conditions. Therefore, when the control transistor Q2 is turned off and the charging switching transistor Q3 is turned on, the charging circuit is turned on and the charging capacitor C2 starts to charge. When the control transistor Q2 is turned on, the source of the voltage-resistant switching transistor Q1 is pulled down to ground, and the source voltage of the voltage-resistant switching transistor Q1 is close to 0V. Therefore, the source voltage of the voltage-resistant switching transistor Q1 is lower than the voltage of the charging capacitor C2, the charging circuit is disconnected, and the charging capacitor C2 stops charging. At this time, the primary circuit is turned on, and the primary coil N1 stores energy.

As shown in FIG. 4 and FIG. 5, in order to ensure that the charging capacitor C2 can store enough electricity for the switching power supply chip PWM to consume during the switching cycle of the switching power supply, the comparison controller 220 includes a current comparator CMPA and a AND logic AND. One input end of the current comparator CMPA is configured to obtain a preset current value Iref, and the other input end is connected to the current sampler 210, which is configured to compare whether the charging current I of the charging branch 100 exceeds the preset current value Iref, and output a comparison signal S1. In the embodiment of the present application, the positive input end of the current comparator CMPA is connected to the current sampler 210, and the preset current value Iref obtained by the reverse input end of the current comparator CMPA can be selected as 100 mA. One input end of the AND logic AND is connected to the switching power supply chip PWM for obtaining the control signal SW, and the other input end is connected to the current comparator CMPA for obtaining the comparison signal S1 output by the current comparator CMPA. The output end of the AND logic AND is connected to the control electrode of the control transistor Q2. In the embodiment of the present application, the charging requirement is whether the charging current I reaches the preset current value Iref, and the level signal output by the AND logic AND is the charging control signal Sq2. According to the logic characteristics of the AND logic AND, when both input ends of the AND logic AND are at high levels, the control transistor Q2 is turned on.

As shown in FIG. 4 and FIG. 5, when the charging circuit is turned on, the primary coil N1 is also storing energy, but the energy storage speed of the primary coil N1 is slow. At the same time, as the turn-on duration of the charging circuit is increased, the charging current I of the charging circuit gradually increases. To ensure that the switching power supply can work normally and prevent the charging capacitor C2 from stopping charging and the charging current I being lower than the preset current value Iref, causing the control transistor Q2 to be cut off again, causing the charging circuit to be turned on again, thus affecting the energy storage of the primary coil N1, the comparison controller 220 further includes a trigger RS, which is configured to ensure that the charging circuit can only be turned on once within a switching cycle.

As shown in FIG. 4 and FIG. 5, one input end of the trigger RS is connected to the switching power supply chip PWM for obtaining the control signal SW, and the other input end of the trigger RS is connected to the current comparator CMPA for obtaining the comparison signal S1 output by the current comparator CMPA. The trigger RS outputs a trigger signal according to the comparison signal S1 and the control signal SW, and the output end of the trigger RS is connected to the input end of the AND logic AND. In the embodiment of the present application, the current comparator CMPA outputs a high level signal when the charging current I is greater than the preset current value Iref, so the trigger is a RS trigger, the reset end of the trigger RS is connected to the switching power supply chip PWM, and the set end of the trigger RS is connected to the output end of the current comparator CMPA. A not gate NOT1 is provided between the trigger RS and the switching power supply chip PWM. When the control signal SW output by the switching power supply chip PWM is at a high level, under the action of the not gate NOT1, a low level signal is input to the reset end of the trigger RS. At this time, if the comparison signal S1 output by the current comparator CMPA is at a high level, the trigger RS outputs a high level signal, and both input ends of the AND logic AND are at a high level, and the control transistor Q2 is turned on. When the control signal SW output by the switching power supply chip PWM maintains a high-level output, even if the set end of the trigger RS transitions to a low level signal, the trigger signal output by the output end of the trigger RS is still at a high level. When the control signal SW output by the switching power supply chip PWM transitions to a low level, the output of the output end of the trigger RS transitions to a low level signal, and the control transistor Q2 is turned off.

The self-powering principle of the self-powered circuit of the switching power supply based on the discontinuous conduction mode in an embodiment of the present application is as follows: when the control signal SW output by the switching power supply chip PWM is a high level signal, the charging switching transistor Q3 is turned on, and the charging current I starts to rise from 0. The current sampler 210 samples the current of the charging circuit in real time and outputs the sampling signal CS to the current comparator CMPA. When the sampling signal CS received by the current comparator CMPA is not greater than the preset current value Iref, the current comparator CMPA outputs a low level signal. At this time, the set end of the trigger RS is a low-level input, and the reset end of the trigger RS is also a low-level input. The trigger signal output by the trigger RS maintains a low-level output, and the input end of the AND logic AND connected to the the trigger RS is a low-level input. Therefore, the AND logic AND outputs a low level signal, and the control transistor Q2 remains cut off, and the charging circuit is turned on to charge the charging capacitor C2

When the sampling signal CS received by the current comparator CMPA is greater than the preset current value Iref, the current comparator CMPA outputs a high level signal. At this time, the set end of the trigger RS is a high-level input, and the reset end of the trigger RS is a low-level input. According to the characteristics of the RS trigger, when the control signal SW output by the switching power supply chip PWM does not transition to a low level, the trigger signals output by the trigger RS are all high level signals, and the two input ends of the AND logic AND are both high-level inputs. The AND logic AND outputs a high level, so the control transistor Q2 is turned on, and the source of the voltage-resistant switching transistor Q1 is grounded. At this time, the charging capacitor C2 stops charging to ensure that the primary coil N1 can store energy normally.

When the control signal SW output by the switching power supply chip PWM is at a low level, the charging switching transistor Q3 is turned off, and the comparison signal S1 output by the current comparator CMPA is at a low level. Therefore, the set end of the trigger RS is a low level input, and the reset end of the trigger RS is a high level input. Therefore, the trigger signal output by the trigger RS is a low level signal, and the two input ends of the AND logic AND are both low level inputs. The control transistor Q2 is turned off, and the primary circuit is disconnected at this time, and the secondary coil N2 supplies power to the load.

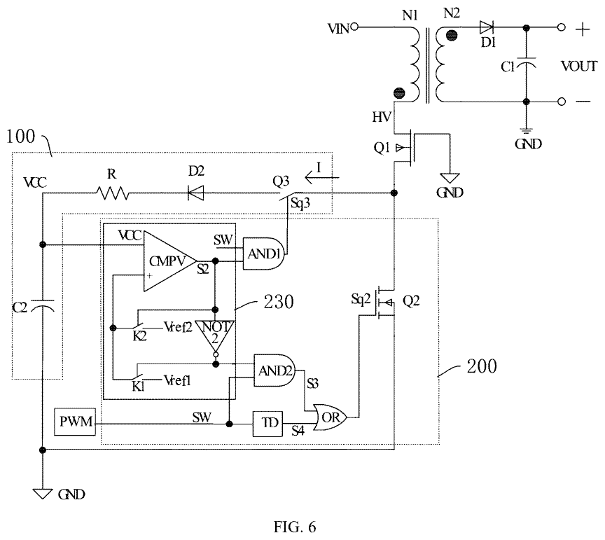

In another embodiment, as shown in FIG. 6, the charging control unit 200 is a voltage sampling control unit, which includes: a control transistor Q2, a voltage sampler 230 and a first AND logic AND1.

The control transistor Q2 is connected between the voltage-resistant switching transistor Q1 and the ground, and the control transistor Q2 is provided in parallel with the charging switching transistor Q3 and the charging capacitor C2. The control transistor Q2 is configured to control whether the source of the voltage-resistant switching transistor Q1 is grounded.

An input end of the voltage sampler 230 is connected to one end of the charging capacitor C2, and the voltage sampler 230 is configured to obtain the voltage signal VCC of the charging capacitor C2 and output a judgment signal S2. An output end of the voltage sampler 230 is connected to the control electrode of the control transistor Q2, and the voltage sampler 230 is configured to control the control transistor Q2 to be turned on or off.

An input end of the first AND logic AND1 is connected to the voltage sampler 230 and the switching power supply chip PWM, and the first AND logic AND1 is configured to receive the judgment signal S2 and the control signal SW. The output end of the first AND logic AND1 is connected to the control electrode of the charging switching transistor Q3, and the first AND logic AND is configured to control the charging switching transistor Q3 to be turned on or off according to the judgment signal S2 and the control signal SW.

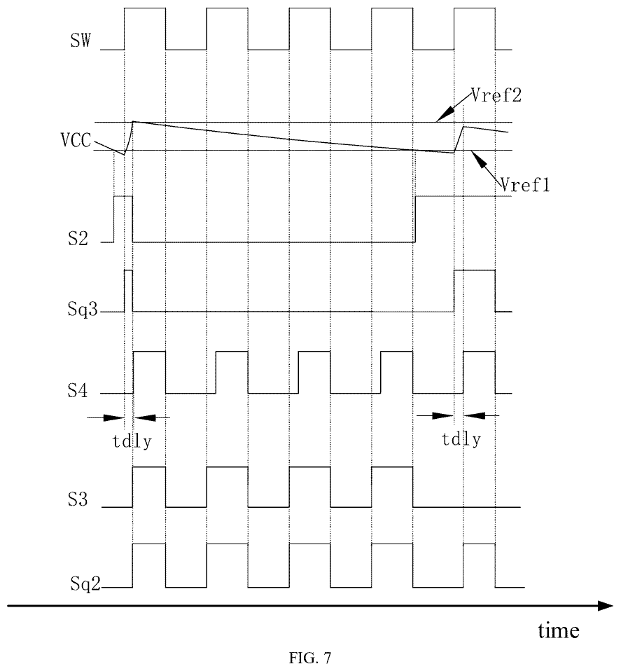

Specifically, as shown in FIG. 6 and FIG. 7, the primary coil N1, the voltage-resistant switching transistor Q1 and the control transistor Q2 constitute a primary circuit, and when the control transistor Q2 is turned on, the primary circuit is turned on. The control transistor Q2 is not limited to a switching transistor such as a MOSFET or a triode. The drain of the voltage-resistant switching transistor Q1 is connected to the primary coil N1, the gate of the voltage-resistant switching transistor Q1 is grounded. The source of the voltage-resistant switching transistor Q1 is connected to the drain of the control transistor Q2, and the source of the control transistor Q2 is grounded. Since the voltage-resistant switching transistor Q1 adopts a depletion gallium nitride transistor, it is in the on state under normal conditions. Therefore, when the control transistor Q2 is turned off and the charging switching transistor Q3 is turned on, the charging circuit is turned on and the charging capacitor C2 starts to charge. When the control transistor Q2 is turned on, the source of the voltage-resistant switching transistor Q1 is pulled down to ground, and the source voltage of the voltage-resistant switching transistor Q1 is close to 0V. Therefore, the source voltage of the voltage-resistant switching transistor Q1 is lower than the voltage of the charging capacitor C2, the charging circuit is disconnected, and the charging capacitor C2 stops charging. At this time, the primary circuit is turned on, and the primary coil N1 stores energy.

As shown in FIG. 6 and FIG. 7, in order to ensure that the charging capacitor C2 can store enough electric energy to meet the energy consumption of the switching power supply chip PWM, the voltage sampler 230 is preset with a low voltage reference value Vref1 and a high voltage reference value Vref2. The voltage value of the low voltage reference value Vref1 is less than the voltage value of the high voltage reference value Vref2, so that the charging capacitor C2 outputs a judgment signal S2 when its voltage signal VCC is less than the low voltage reference value Vref1 or greater than the high voltage reference value Vref2. The judgment signal S2 includes a charging signal and a high voltage signal. When the voltage signal VCC is less than the low voltage reference value Vref1, the voltage sampler 230 outputs a charging signal. When the voltage signal VCC is greater than the high voltage reference value Vref2, the voltage sampler 230 outputs a high voltage signal. The voltage sampler 230 first compares the voltage signal VCC with the low voltage reference value Vref1. When the voltage signal VCC is less than the low voltage reference value Vref1, the voltage sampler 230 outputs a charging signal. At the same time, the voltage sampler 230 compares the voltage signal VCC with the high voltage reference value Vref2. When the voltage signal VCC is greater than the high voltage reference value Vref2, the voltage sampler 230 outputs a high voltage signal. At this time, the voltage sampler 230 compares the voltage signal VCC with the low voltage reference value Vref1 again.

As shown in FIG. 6 and FIG. 7, in order to ensure that the reference signal obtained by the voltage sampler 230 can transition from the low voltage reference value Vref1 to the high voltage reference value Vref2 during the charging process of the charging capacitor C2, the voltage sampler 230 includes a voltage comparator CMPV, a low voltage reference circuit and a high voltage reference circuit provided at an input end of the voltage comparator CMPV. The low voltage reference circuit is configured to provide the low voltage reference value Vref1, and the high voltage reference circuit is configured to provide the high voltage reference value Vref2. A first conductive element is provided between the output end of the voltage comparator CMPV and the low voltage reference circuit, and a second conductive element is provided between the output end of the voltage comparator CMPV and the high voltage reference circuit. The conduction conditions of the first conductive element and the second conductive element are opposite, so that the low voltage reference circuit and the high voltage reference circuit cannot be connected to the voltage comparator CMPV at the same time.

As shown in FIG. 6 and FIG. 7, in the embodiment of the present application, the first conductive element includes a first switch K1 and a NOT logic NOT2, and the second conductive element includes a second switch K2. The first switch K1 and the second switch K2 have the same conduction conditions. The first switch K1 controls whether the low voltage reference circuit is connected to the voltage comparator CMPV according to the judgment signal S2 processed by the NOT logic NOT2. The second switch K2 controls whether the high voltage reference circuit is connected to the voltage comparator CMPV according to the judgment signal S2. Under the action of the NOT logic NOT2, the low voltage reference circuit and the high voltage reference circuit cannot be connected to the voltage comparator CMPV at the same time.

As shown in FIG. 6 and FIG. 7, in the embodiment of the present application, the low voltage reference circuit or the high voltage reference circuit is connected to the positive input end of the voltage comparator CMPV, the reverse input end of the voltage comparator CMPV is connected to one end of the charging capacitor C2, the output end of the voltage comparator CMPV is connected to one input end of the first AND logic AND1, and the other input end of the first AND logic AND1 is connected to the switching power supply chip PWM. When both input ends of the first AND logic AND1 are high level inputs, the charging switching transistor Q3 is turned on, and the charging circuit is turned on at this time, and the charging capacitor C2 is charged. When one of the input ends or both input ends of the first AND logic AND1 input a low level signal, the first AND logic AND1 outputs a low level signal, and the charging switching transistor Q3 is turned off. At this time, the charging circuit is disconnected, and the charging capacitor C2 stops charging.

As shown in FIG. 6 and FIG. 7, a second AND logic AND2 is provided between the voltage comparator CMPV and the control transistor Q2, one input end of the second AND logic AND2 is connected to the output end of the NOT logic NOT2, the other input end of the second AND logic AND2 is connected to the switching power supply chip PWM, and the output end of the second AND logic AND2 is coupled to the control electrode of the control transistor Q2. When both input ends of the second AND logic AND2 are high level signals, the control transistor Q2 is turned on and the primary circuit is turned on. When one or both input ends of the second AND logic AND2 are input with a low level signal, the second AND logic AND2 outputs a low level signal, the control transistor Q2 is turned off, and the primary circuit is disconnected, and the secondary coil N2 supplies power to the load.

As shown in FIG. 6 and FIG. 7, when the charging capacitor C2 is fully charged, the judgment signal S2 output by the voltage comparator CMPV a high-voltage signal, that is a low-level signal. At this time, the connection between the high voltage reference circuit and the voltage comparator CMPV is disconnected. Under the action of the NOT logic NOT2, the low voltage reference circuit is connected to the voltage comparator CMPV, and the voltage comparator CMPV obtains the low voltage reference value Vref1. Therefore, the voltage comparator CMPV is connected to the low voltage reference circuit after the charging capacitor C2 is charged until the next charging begins When the charging capacitor C2 needs to be recharged, the voltage comparator CMPV is disconnected from the low voltage reference circuit and connected to the high voltage reference circuit until the charging of the charging capacitor C2 is completed. In the embodiment of the present application, by designing the voltage value of the low voltage reference value Vref1, when the control signal SW output by the switching power supply chip PWM transitions from a low level to a high level, the judgment signal S2 output by the voltage comparator CMPV is a charging signal. That is, when the control signal SW transitions from a low level to a high level, the voltage comparator CMPV outputs a high level signal, and the charging capacitor C2 is in a state of needing to be recharged. At this time, the second conductive element is closed to control the high voltage reference circuit to be connected to the voltage comparator CMPV, the first AND logic AND1 outputs a high level signal, the charging switching transistor Q3 is turned on, and the charging capacitor C2 is charged, so the voltage of the charging capacitor C2 gradually increases. When the voltage signal VCC obtained by the voltage comparator CMPV is greater than the high voltage reference value Vref2, the voltage comparator CMPV outputs a low level signal. At this time the second switch K2 controls the high voltage reference circuit to be disconnected from the voltage comparator CMPV, and the first switch K1 controls the low voltage reference circuit to be connected to the voltage comparator CMPV under the action of the NOT logic NOT2.

As shown in FIG. 6 and FIG. 7, further, in order to prevent the charging capacitor C2 from failing to reach the high voltage reference value Vref2 and causing the primary coil N1 to fail to store energy normally, the charging control unit 200 also includes a delay TD and an OR logic OR. The delay TD is preset with a preset duration tdly, the input end of the delay TD is connected to the switching power supply chip PWM, and the output end of the delay TD is connected to the control electrode of the control transistor Q2. The delay TD is triggered by a high level signal, that is, when the control signal SW is at a high level, the delay TD starts timing, and when within the preset duration tdly, the delay TD still maintains a low-level output. When the timing duration reaches the preset duration tdly, the delay TD outputs a high level. The two input ends of the OR logic OR are respectively connected to the output end of the second AND logic AND2 and the output end of the delay TD, and the output end of the OR logic OR is connected to the control electrode of the control transistor Q2. In the embodiment of the present application, the charging requirement is whether the charging time reaches the preset duration tdly or whether the voltage of the charging capacitor C2 reaches the high voltage reference value Vref2. Therefore, the level signal output by the OR logic OR is the charging control signal Sq2. Under the action of the OR logic OR, when either the delay TD or the second AND logic AND2 outputs a high level, the control transistor Q2 is turned on. When the control transistor Q2 is turned on, the primary circuit is turned on to ensure that the primary coil N1 can store energy normally.

The self-powering principle of the self-powered circuit of the switching power supply based on the discontinuous conduction mode in an embodiment of the present application is as follows: when the control signal SW output by the switching power supply chip PWM is a high level signal, the initial judgment signal S2 of the voltage comparator CMPV is a high level signal. At this time, the charging switching transistor Q3 is turned on, the high voltage reference circuit is connected to the voltage comparator CMPV, and the voltage signal VCC is compared with the high voltage reference value Vref2. At the same time, the charging current I starts to rise from 0, and the voltage sampler 230 samples the voltage of the charging capacitor C2 in real time and outputs a voltage VOUT signal to the voltage comparator CMPV. When the voltage signal VCC received by the voltage comparator CMPV is not greater than the high voltage reference value Vref2, the voltage comparator CMPV outputs a high level signal, the first AND logic AND1 maintains a high-level output, the charging switching transistor Q3 remains turned on, the control transistor Q2 remains turned off, and the charging circuit is turned on to charge the charging capacitor C2.

When the voltage signal VCC received by the voltage comparator is greater than the high voltage reference value Vref2, the voltage comparator CMPV outputs a low level signal. At this time, the first AND logic AND1 outputs a low level signal, the charging switching transistor Q3 is turned off, and the charging capacitor C2 stops charging. At the same time, the low voltage reference circuit is connected to the voltage comparator CMPV, the voltage signal VCC is compared with the low voltage reference value Vref1, and the second AND logic AND2 outputs a high level signal, so that the control transistor Q2 is turned on, and the primary circuit is turned on to ensure that the primary coil N1 can store energy normally.

When the control signal SW output by the switching power supply chip PWM is a high level signal, the delay TD starts timing. When the timing duration of the delay TD reaches the preset duration tdly, the delay TD outputs a high level signal. At this time, a high level signal is input to one end of the OR logic OR connected to the delay TD, or the charging control signal Sq2 output by the OR logic OR is a high level signal. At this time, the control transistor Q2 is turned on, and the source of the voltage-resistant switching transistor Q1 is grounded. Regardless of whether the voltage of the charging capacitor C2 is greater than the high voltage reference value Vref2, the charging circuit is disconnected.

When the control signal SW output by the switching power supply chip PWM is at a low level, the first AND logic AND1 outputs a low level signal, the charging switching transistor Q3 is turned off. The second AND logic AND2 outputs a low level signal, or the OR logic OR outputs a low level signal, and the control transistor Q2 is turned off. At this time, the primary circuit is disconnected, and the secondary coil N2 supplies power to the load.

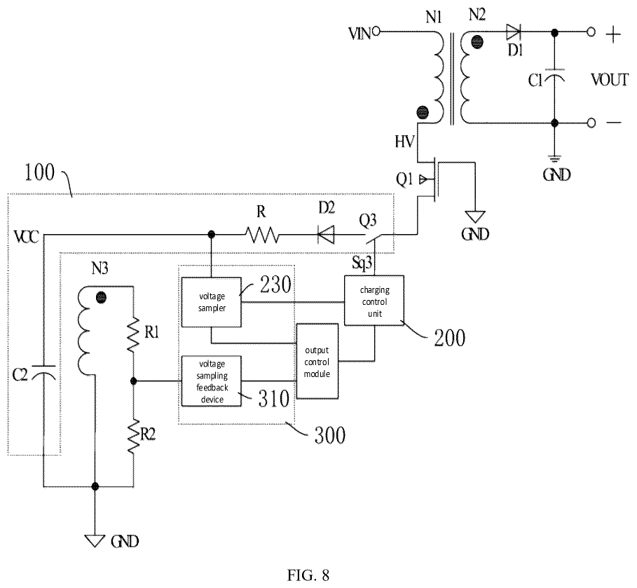

The embodiment of the present application also discloses a self-powered circuit of a switching power supply based on a continuous conduction mode. When the switching power supply is in a continuous conduction mode (CCM), the current flowing in the coil of each switching cycle has not yet decreased to 0, and the next switching cycle has arrived. Therefore, when each new switching cycle arrives, the current flowing in the coil starts to rise from a certain value (non-zero value). Since the area of the device is related to the resistant voltage and the current flowing through the device, the higher the resistant voltage and the larger the current flowing, the corresponding area of the device will also increase. Therefore, in order to reduce the area of the self-powered circuit in the embodiment of the present application, the self-powered circuit is designed so that when the charging capacitor C2 is recharged, the current flowing in the coil of the switching power supply starts to rise from 0. As shown in FIG. 8, the self-powered circuit includes a voltage-resistant switching transistor Q1, a charging branch 100, a mode switching unit 300 and a charging control unit 200, the charging branch 100 includes a charging capacitor C2, a charging switching transistor Q3 and a protection resistor R.

The voltage-resistant switching transistor Q1 is connected between the primary coil N1 and the charging capacitor C2, obtains the power supply voltage of the primary coil N1, and outputs the charging voltage for charging the charging capacitor C2.

The charging capacitor C2 draws power from the primary coil N1 and supplies power to the switching power supply chip PWM.

The charging switching transistor Q3 is connected between the charging capacitor C2 and the voltage-resistant switching transistor Q1. The charging switching transistor Q3 is configured to control whether to charge the charging capacitor C2 when the voltage-resistant switching transistor Q1 is turned on and outputs the charging voltage.

The protection resistor R is connected in series between the charging switching transistor Q3 and the charging capacitor C2 to protect the charging capacitor C2. The mode switching unit 300 is configured to monitor the voltage of the charging capacitor C2 and the voltage of the auxiliary coil N3, and output a switching signal for adjusting the output of the control signal SW of the switching power supply chip PWM.

The charging control unit 200 is configured to control whether the charging branch 100 is turned on.

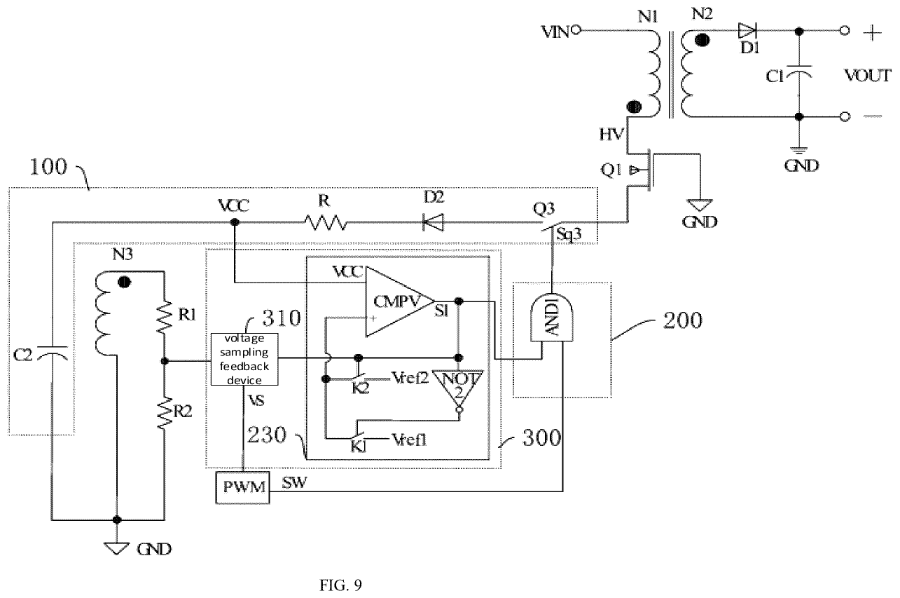

Specifically, as shown in FIG. 8 and FIG. 9, the mode switching unit 300 includes a voltage sampler 230 and a voltage sampling feedback device 310. The voltage sampler 230 is preset with a low voltage reference value Vref1 and a high voltage reference value Vref2, and the low voltage reference value Vref1 is less than the high voltage reference value Vref2. The voltage sampler 230 is configured to obtain the voltage signal VCC of the charging capacitor C2 and output a judgment signal S2 after comparing the voltage signal VCC with the low voltage reference value Vref1 or the high voltage reference value Vref2. The judgment signal S2 includes a low voltage supplementary power signal, a charging signal and a full power signal. When the voltage signal VCC is less than the low voltage reference value Vref1, the low voltage supplementary power signal is output. When the voltage signal VCC is greater than the low voltage reference value Vref1 and less than the high voltage reference value Vref2, the charging signal is output. When the voltage signal VCC is greater than the high voltage reference value Vref2, the full power signal is output. By setting the high voltage reference value Vref2, the charging capacitor C2 can be fully charged to meet the energy consumption of the switching power supply chip PWM for at least two switching cycles. By setting the low voltage reference value Vref1, the low voltage supplementary power signal is output in the low level signal segment of the control signal SW output by the switching power supply chip PWM, and the charging capacitor C2 still has enough power to meet the energy consumption of the switching power supply chip PWM before the next switching cycle arrives.

As shown in FIG. 8 and FIG. 9, the voltage sampling feedback device 310 is disposed between the auxiliary coil N3 and the switching power supply chip PWM, and samples the voltage on the auxiliary coil N3 to obtain the sampling signal CS. The switching power supply chip PWM receives the sampling signal CS and determines whether the secondary coil N2 is fully discharged through the sampling signal CS. In the embodiment of the present application, the level signals output by the low voltage supplementary power signal and the charging signal are the same, so the switching signal includes the sampling signal CS and the low voltage supplementary power signal or the charging signal. When the switching power supply chip PWM does not receive the low voltage supplementary power signal, it means that the charging capacitor C2 does not need to be recharged, and the switching power supply chip PWM does not need to adjust the control signal SW to charge the charging capacitor C2, and the switching power supply still operates in the continuous conduction mode. When the switching power supply chip PWM receives the low voltage supplementary power signal, the switching power supply chip PWM prolongs the duration of the control signal being at a low level, so that the switching power supply is converted from the continuous conduction mode to the discontinuous conduction mode. When the switching power supply chip PWM determines that the secondary coil N2 is fully discharged through the sampling signal CS, the control signal SW output by the switching power supply chip PWM is converted from a low level to a high level. At this time, the charging control unit 200 controls the charging branch 100 to be turned on, so that the charging capacitor C2 is charged. Because the secondary coil N2 of the switching power supply is fully discharged before the switching power supply chip PWM outputs a high level signal, the current flowing in the coil starts to rise from 0 when the control signal SW is a high level signal.

As shown in FIG. 8 and FIG. 9, the primary coil N1, the voltage-resistant switching transistor Q1 and the charging branch 100 constitute a charging circuit for charging the charging capacitor C2. The drain of the voltage-resistant switching transistor Q1 is connected to the primary coil N1, the gate of the voltage-resistant switching transistor Q1 is grounded. The charging control unit 200 is connected in series between the voltage-resistant switching transistor Q1 and the ground. The charging control unit 200 has a preset charging requirement and outputs a charging control signal Sq2. The charging control signal Sq2 is configured to control whether the charging branch 100 that is turned on continues to remain turned on. In the embodiment of the present application, whether the charging branch 100 is turned on is determined by the voltage of the charging capacitor C2.

As shown in FIG. 8 and FIG. 9, in the embodiment of the present application, the charging capacitor C2 can be charged only when the switching power supply chip PWM receives the low voltage supplementary power signal output by the voltage sampler 230 and the switching power supply chip PWM outputs a high level signal. Therefore, the control electrode of the charging switching transistor Q3 is connected to the switching power supply chip PWM and is controlled by the control signal SW output by the switching power supply chip PWM. At the same time, the control electrode of the charging switching transistor Q3 is also connected to the output end of the voltage sampler 230 and is controlled by the signal output by the voltage sampler 230. In the embodiment of the present application, when the control electrode of the charging switching transistor Q3 inputs a high level signal, the charging switching transistor Q3 is turned on. The charging switching transistor Q3 is not limited to a MOSFET, a triode, and other switching transistor.

As shown in FIG. 8 and FIG. 9, when the control signal SW output by the switching power supply chip PWM is at a low level, if the voltage sampler 230 detects that the voltage signal VCC is greater than the low voltage reference value Vref1, it means that the electric energy of the charging capacitor C2 is sufficient to maintain the energy consumption of the switching power supply chip PWM, and no additional power is required. If the voltage sampler 230 detects that the voltage signal VCC is less than the low voltage reference value Vref1, it means that the electric energy of the charging capacitor C2 is insufficient to maintain the energy consumption of the switching power supply chip PWM, and additional power is required. At this time, the voltage sampler 230 outputs a low voltage supplementary power signal, and the voltage signal VCC switches from being compared with the low voltage reference value Vref1 to being compared with the high voltage reference value Vref2, and the voltage sampler 230 outputs a charging signal. When the switching power supply chip PWM receives the low voltage supplementary power signal, the switching power supply chip PWM prolongs the duration of the low-level output, and transitions to a high-level output when it receives the sampling signal CS as a resonant voltage signal. When the switching power supply chip PWM outputs a high level signal, if the charging control unit 200 controls the charging branch 100 to be turned on, the charging circuit is turned on and the charging capacitor C2 starts to charge. If the charging control unit 200 controls the charging branch 100 to be turned off, the charging circuit is disconnected and the charging capacitor C2 stops charging.

As shown in FIG. 8 and FIG. 9, the voltage sampler 230 includes a voltage comparator CMPV, a low voltage reference circuit and a high voltage reference circuit provided at an input end of the voltage comparator CMPV. The low voltage reference circuit is configured to provide a low voltage reference value Vref1, and the high voltage reference circuit is configured to provide a high voltage reference value Vref2. A first conductive element is provided between the output end of the voltage comparator CMPV and the low voltage reference circuit, and a second conductive element is provided between the output end of the voltage comparator CMPV and the high voltage reference circuit, and the first conductive element and the second conductive element have opposite conduction conditions, so as to realize that the high voltage reference circuit and the low voltage reference circuit cannot be connected to the voltage comparator CMPV at the same time.

As shown in FIG. 8 and FIG. 9, in the embodiment of the present application, the first conductive element includes a first switch K1 and a NOT logic NOT2, and the second conductive element includes a second switch K2. The first switch K1 and the second switch K2 have the same conduction conditions. The first switch K1 controls whether the low voltage reference circuit is connected to the voltage comparator CMPV according to the judgment signal S2 processed by the NOT logic NOT2, and the second switch K2 controls whether the high voltage reference circuit is connected to the voltage comparator CMPV according to the judgment signal S2. Under the action of the NOT logic NOT2, the low voltage reference circuit and the high voltage reference circuit cannot be connected to the voltage comparator CMPV at the same time.

As shown in FIG. 8 and FIG. 9, in the embodiment of the present application, the low voltage reference circuit or the high voltage reference circuit is connected to the positive input end of the voltage comparator CMPV, and the reverse input end of the voltage comparator CMPV is connected to one end of the charging capacitor C2, so that the low voltage supplementary power signal and the charging signal are both high level signals, and the full power signal is a low level signal. The charging control unit 200 includes a first AND logic AND1, one input end of the first AND logic AND1 is connected to the output end of the voltage comparator CMPV, and the other input end of the first AND logic AND1 is connected to the switching power supply chip PWM. When both input terminals of the first AND logic AND1 are high level inputs, the charging switching transistor Q3 is turned on, and the charging circuit is turned on at this time, and the charging capacitor C2 is charged. When one of the input ends or both input ends of the first AND logic AND1 input a low level signal, the first AND logic AND1 outputs a low level signal, and the charging switching transistor Q3 is turned off, and the charging circuit is disconnected at this time, and the charging capacitor C2 stops charging.

As shown in FIG. 8 and FIG. 9, when the charging capacitor C2 is fully charged, the signal output by the voltage comparator CMPV is a full power signal, and the reverse input end of the voltage comparator CMPV is connected to the charging capacitor C2, so that the full power signal is a low level signal. At this time, the connection between the high voltage reference circuit and the voltage comparator CMPV is disconnected. Under the action of the NOT logic NOT2, the low voltage reference circuit is connected to the voltage comparator CMPV, and the voltage comparator CMPV obtains the low voltage reference value Vref1. Therefore, the voltage comparator CMPV is connected to the low voltage reference circuit after the charging capacitor C2 is charged until the next charging begins. If the voltage value of the charging capacitor C2 is greater than the low voltage reference value Vref1, it means that the charging capacitor C2 does not need to be recharged. When the voltage value of the charging capacitor C2 is less than the low voltage reference value Vref1, it means that the charging capacitor C2 needs to be recharged. At this time, the voltage comparator CMPV outputs a low voltage supplementary power signal, and the low voltage supplementary power signal is a high level signal. At the same time, under the action of the NOT logic NOT2, the voltage comparator CMPV is disconnected from the low voltage reference circuit, and the voltage comparator CMPV is connected to the high voltage reference circuit until the charging of the charging capacitor C2 is completed.

As shown in FIG. 8 and FIG. 9, in order to further reduce the area of the self-powered circuit, in the embodiment of the present application, the voltage-resistant switching transistor Q1 adopts a depletion gallium nitride transistor. Since the area of the device is related to the resistant voltage and the current flowing through the device, the higher the resistant voltage and the greater the current flowing, the corresponding area of the device will also increase. The gallium nitride transistor is used as a high-voltage switching transistor, its working characteristics can be configured to take power from the source end of the voltage-resistant switching transistor Q1 to ensure that the chip only works in a low-voltage state, so as to meet the high resistant voltage requirements of the device, reduce the complexity of the device, thereby reducing the final device area.

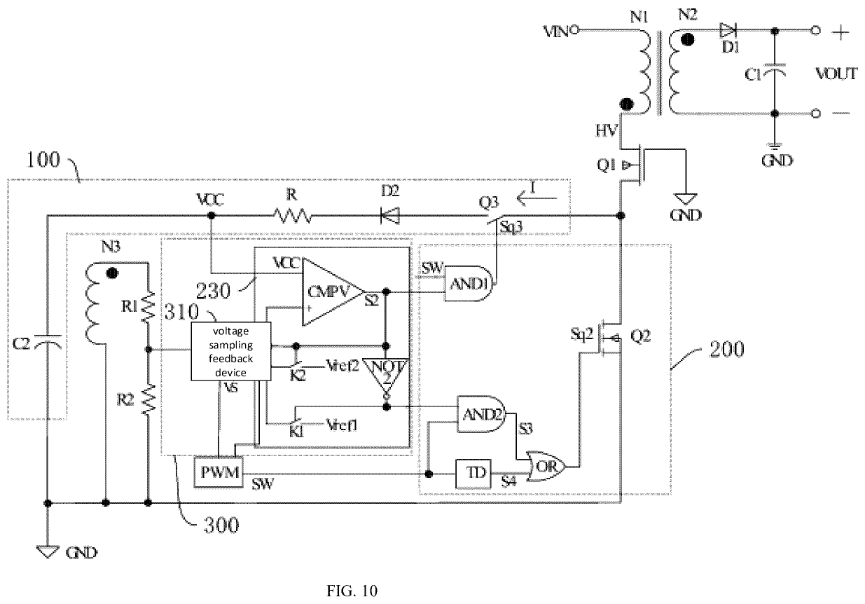

In an embodiment, as shown in FIG. 10, the charging control unit 200 is a delay control unit, which further includes: a control transistor Q2, a delay TD, a second AND logic AND2, and an OR logic OR.

The control transistor Q2 is connected between the voltage-resistant switching transistor Q1 and the ground, and the control transistor Q2 is provided in parallel with the charging switching transistor Q3 and the charging capacitor C2. The control transistor Q2 is configured to control whether the source of the voltage-resistant switching transistor Q1 is grounded.

The delay TD is connected between the control transistor Q2 and the switching power supply chip PWM, and is configured to delay the output of the control signal SW output by the switching power supply chip PWM.

The second AND logic AND2, whose input end is connected to the voltage sampler 230 and the switching power supply chip PWM, is configured to receive the judgment signal S2 and the control signal SW, and output the voltage identification signal S3 according to the judgment signal S2 and the control signal SW.

The OR logic OR, whose input end is connected to the output end of the delay TD and the output end of the second AND logic AND2 respectively, and the OR logic OR is configured to obtain the control signal SW and the voltage identification signal S3 delayed by the delay TD. The output end of the OR logic OR is connected to the control electrode of the control transistor Q2, and OR logic OR is configured to control the control transistor Q2 to be turned on or off.

In the embodiment of the present application, when the control end of the control transistor Q2 is at a high level, the control transistor Q2 is turned on. The control transistor Q2 is not limited to a switching transistor such as a MOSFET or a triode.

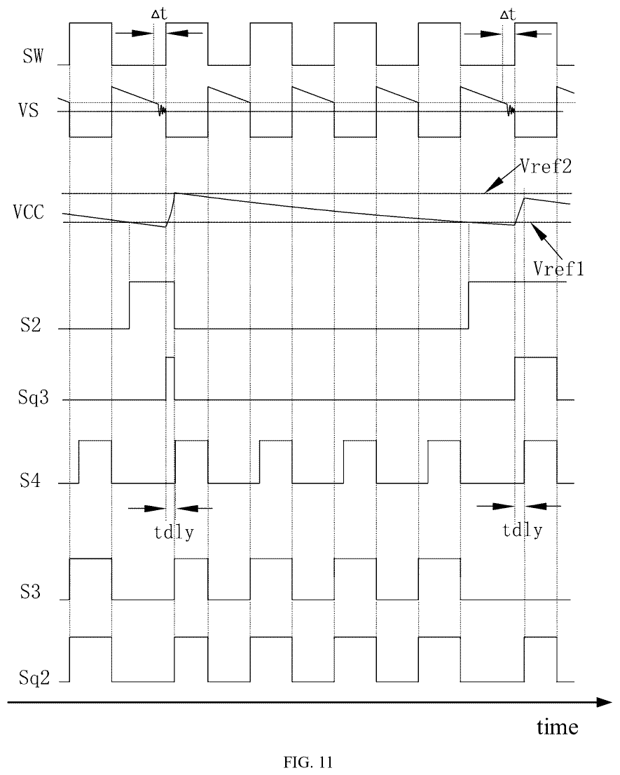

Specifically, as shown in FIG. 10 and FIG. 11, the primary coil N1, the voltage-resistant switching transistor Q1 and the control transistor Q2 constitute the primary circuit. When the control transistor Q2 is turned on, the primary circuit is turned on. Since the energy storage of the primary coil N1 is affected when the charging circuit is turned on, in order to ensure that the primary coil N1 can store energy normally, the delay TD is provided with a preset duration tdly, and the input end of the delay TD is connected to the switching power supply chip PWM. The delay TD is triggered by a high level signal, that is, when the control signal SW is at a high level, the delay TD starts timing. When the timing duration is within the preset duration tdly, the delay TD still maintains a low-level output. At this time, the control electrode of the control transistor Q2 inputs a low level signal. When the timing duration reaches the preset duration tdly, the delay TD outputs a high level. The preset duration not only ensures that the charging capacitor C2 has an appropriate charging time, but also ensures that the primary coil N1 can store energy normally. In the embodiment of the present application, the charging requirement is whether the voltage of the charging capacitor C2 reaches the high voltage reference value Vref2 and/or whether the charging time reaches the preset duration tdly, so that the level signal output by the OR logic OR is the charging control signal Sq2. According to the characteristics of the OR logic OR, when either the delay TD or the second AND logic AND2 outputs a high level, the control transistor Q2 is turned on. When the control transistor Q2 is turned on, the primary circuit is turned on to ensure that the primary coil N1 can store energy normally

As shown in FIG. 10 and FIG. 11, since the voltage-resistant switching transistor Q1 adopts a depletion gallium nitride transistor, it is in the on state under normal conditions. Therefore, when the control transistor Q2 is turned off and the charging switching transistor Q3 is turned on, the charging circuit is turned on and the charging capacitor C2 starts to charge. Under the action of the delay TD, if the timing duration reaches the preset duration tdly and the voltage value of the charging capacitor C2 is still less than the high voltage reference value Vref2, the delay TD outputs a high level to turn on the control transistor Q2. At this time, the source of the voltage-resistant switching transistor Q1 is pulled down to ground, and the source voltage of the voltage-resistant switching transistor Q1 is close to 0V. Therefore, the source voltage of the voltage-resistant switching transistor Q1 is lower than the voltage of the charging capacitor C2, the charging circuit is disconnected, and the charging capacitor C2 stops charging. At this time, the primary circuit is turned on and the primary coil N1 stores energy. When the control transistor Q2 is turned on, the unidirectional conducting transistor D2 is reversely turned off, the charging branch 100 is turned off, and the charging capacitor C2 stops charging, and it will not discharge to the ground through the charging switching transistor Q3 and the control transistor Q2.

As shown in FIG. 10 and FIG. 11, when the timing duration of the delay TD reaches the preset duration tdly, and the voltage value of the charging capacitor C2 is still less than the high voltage reference value Vref2, the voltage comparator CMPV outputs a charging signal. That is, the level signal output by the voltage comparator CMPV to the switching power supply chip PWM is still a high level signal, so that when the switching power supply chip PWM still prolongs its low level signal output duration, and the switching power supply chip PWM determines through the sampling signal CS that the secondary coil N2 is fully discharged, the control signal SW output by the switching power supply chip PWM is converted from a low level signal to a high level signal.

The self-powering principle of the self-powered circuit of the switching power supply based on the continuous conduction mode in an embodiment of the present application is as follows: when the voltage comparator CMPV detects that the voltage signal VCC is less than the low voltage reference value Vref1, the voltage comparator CMPV outputs a low voltage supplementary power signal, and the low voltage supplementary power signal is a high level signal. At this time, under the action of the NOT logic NOT2, the first conductive element controls the low voltage reference circuit to be disconnected from the voltage comparator CMPV, and the second conductive element controls the high voltage reference circuit to be connected to the voltage comparator CMPV. At this time, the voltage comparator CMPV compares the voltage signal VCC with the high voltage reference value Vref2. During the period when the voltage signal VCC is lower than the high voltage reference value Vref2, the voltage comparator CMPV outputs a charging signal, and the charging signal is a high level signal.

When the control signal SW output by the switching power supply chip PWM is a low level signal, if the voltage sampling feedback device 310 outputs a low voltage supplementary power signal, the switching power supply chip PWM prolongs the duration of the control signal SW being at a low level, and the switching power supply is switched from continuous conduction mode to discontinuous conduction mode, so that the energy of the coil can be fully discharged. At the same time, the voltage sampling feedback device 310 samples the voltage of the secondary coil N2 and transmits the sampling signal CS to the switching power supply chip PWM. When the switching power supply chip PWM detects that the sampling signal CS is a resonant voltage, the switching power supply chip PWM outputs a high level signal.

When the switching power supply chip PWM outputs a high level signal, both input ends of the first AND logic AND1 are high level signal inputs, so that the first AND logic AND1 outputs a high level signal, the charging switching transistor Q3 is turned on, the charging circuit is turned on, and the charging capacitor C2 starts to charge. At the same time, the delay TD starts timing. When the timing duration does not reach the preset duration tdly, if the voltage signal VCC obtained by the voltage comparator CMPV is greater than the high voltage reference value Vref2, the voltage comparator CMPV outputs a full power signal, and the full power signal is a low level signal. At this time, one input end of the first AND logic AND1 is a low-level input, so that the first AND logic AND1 outputs a low level signal, the charging switching transistor Q3 is turned off, the charging circuit is disconnected, and the charging capacitor C2 stops charging. At the same time, both input ends of the second AND logic AND2 are high-level inputs, so that the end of the OR logic OR connected to the second AND logic AND2 is a high-level input, so that the OR logic OR outputs a high level, then the control transistor Q2 is turned on, the primary circuit is turned on, and the primary coil N1 stores energy. When the timing duration of the delay TD reaches the preset duration tdly, the delay TD outputs a high level signal. At this time, both input ends of the OR logic OR are high-level inputs, and the control transistor Q2 remains turned on.

When the timing duration reaches the preset duration tdly, the delay TD outputs a high level. If the voltage signal VCC obtained by the voltage comparator CMPV is still less than the high voltage reference value Vref2, the voltage comparator CMPV outputs a charging signal, and the charging signal is high. At this time, the charging switching transistor Q3 remains turned on. Since the end of the OR logic OR connected to the delay TD is a high-level input, the OR logic OR outputs a high level signal, and the control transistor Q2 is turned on, so that the source of the voltage-resistant switching transistor Q1 is pulled down to ground. Therefore, the source voltage of the voltage-resistant switching transistor Q1 is lower than the voltage of the charging capacitor C2, and the charging circuit is disconnected. The charging capacitor C2 stops charging. At this time, the primary circuit is turned on, and the primary coil N1 stores energy. During the next time the switching power supply chip PWM outputs a low level signal, since the voltage comparator CMPV outputs a high level signal, the switching power supply chip PWM will still prolong the duration of the control signal SW being a low level signal, so that the switching power supply works in a discontinuous conduction mode, ensuring that when the next switching cycle arrives, the secondary coil N2 is fully discharged, and the charging capacitor C2 can be charged from a current value of 0.

When the switching power supply outputs a low level signal, the first AND logic AND1 outputs a low level signal, the charging switching transistor Q3 is turned off, the second AND logic AND2 outputs a low level signal, and the delay TD also outputs a low level signal, so the OR logic OR outputs a low level signal, and the control transistor Q2 is turned off. At this time, the primary circuit is disconnected, and the secondary coil N2 supplies power to the load.

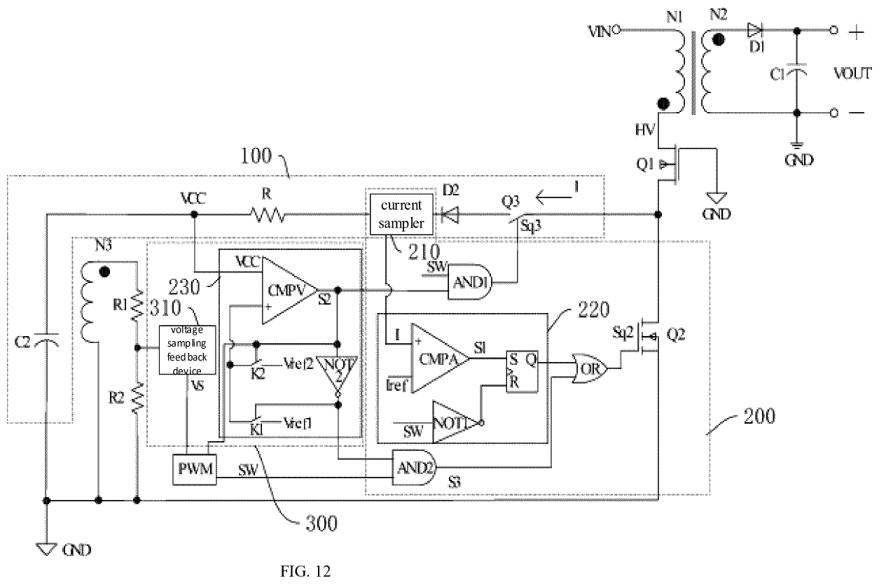

In an embodiment, as shown in FIG. 12, the charging control unit 200 is a current sampling control unit, which further includes: a control transistor Q2, a current sampler 210, a comparison controller 220, a second AND logic AND2 and an OR logic OR.

The control transistor Q2 is connected between the voltage-resistant switching transistor Q1 and the ground, and the control transistor Q2 is provided in parallel with the charging switching transistor Q3 and the charging capacitor C2. The control transistor Q2 is configured to control whether the source of the voltage-resistant switching transistor Q1 is grounded.

The current sampler 210 is connected in series to the charging branch 100, and is configured to detect the charging current I of the charging branch 100, and output a sampling signal CS proportional to the charging current I.

The comparison controller 220 has an input end connected to the current sampler 210 and the switching power supply chip PWM, the comparison controller 220 is configured to receive the sampling signal CS and the control signal SW, and output a current identification signal according to the sampling signal CS and the control signal SW.

The second AND logic AND2, whose input end is connected to the voltage sampler 230 and the switching power supply chip PWM, the second AND logic AND2 is configured to receive the judgment signal S2 and the control signal SW, and output the voltage identification signal S3 according to the judgment signal S2 and the control signal SW.

The input end of the OR logic OR is respectively connected to the output end of the comparison controller 220 and the output end of the second AND logic AND2, and the OR logic OR is configured to obtain the current identification signal and the voltage identification signal S3. The output end of the OR logic OR is connected to the control electrode of the control transistor Q2, and the OR logic OR is configured to control the control transistor Q2 to be turned on or off.

In the embodiment of the present application, when the control end of the control transistor Q2 is at a high level, the control transistor Q2 is turned on. The control transistor Q2 is not limited to a switching transistor such as a MOSFET and a triode.

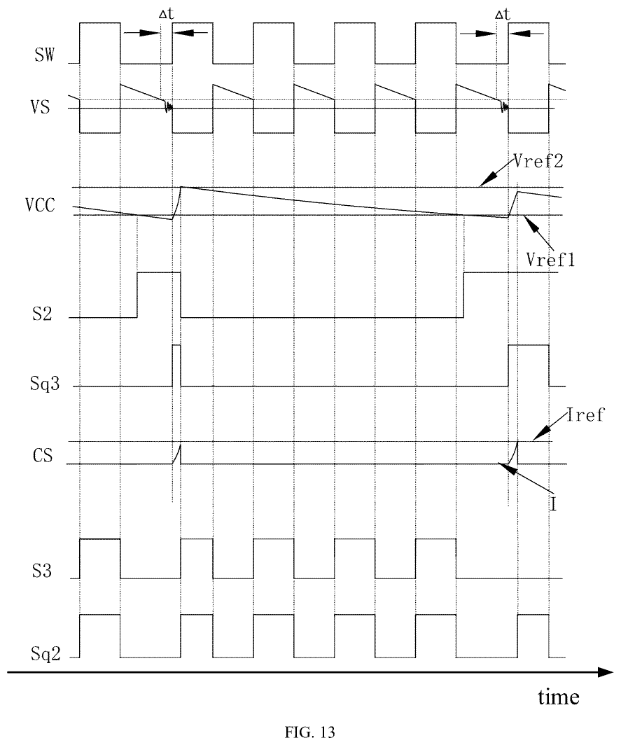

Specifically, as shown in FIG. 12 and FIG. 13, the primary coil N1, the voltage-resistant switching transistor Q1 and the control transistor Q2 constitute a primary circuit, and when the control transistor Q2 is turned on, the primary circuit is turned on. After the charging circuit is turned on as the turn-on duration increases, the charging current I of the charging capacitor C2 gradually increases. In order to ensure that the charging capacitor C2 is charged with a small current and thus reduce the area of the self-powered circuit, a current sampler 210 is added to the charging circuit to sample the charging current I, and a comparison controller 220 is set at the same time. The comparison controller 220 is preset with a preset current value Iref. When the charging current I of the charging circuit is greater than the preset current value Iref, the comparison controller 220 controls the charging circuit to disconnect to prevent the charging current I of the charging circuit from being too large

The comparison controller 220 includes a current comparator CMPA and a trigger RS. One input end of the current comparator CMPA obtains a preset current value Iref, and the other input end of the current comparator CMPA is connected to the current sampler 210, and the current comparator CMPA is configured to compare whether the charging current I input to the charging circuit exceeds the preset current value Iref, and outputting a comparison signal S1. In the embodiment of the present application, the positive input end of the current comparator CMPA is connected to the current sampler 210, and the preset current value Iref obtained by the reverse input end of the current comparator CMPA can be 100 mA. That is, when the charging current I is greater than the preset current value Iref, the current comparator CMPA outputs a high level signal. In order to prevent the situation that the charging current I drops to 0 after the charging circuit is disconnected and the charging circuit is turned on again within a switching cycle, thereby affecting the energy storage of the primary coil N1, one input end of the trigger RS is connected to the switching power supply chip PWM for obtaining the control signal SW, and the other input end of the trigger RS is connected to the output end of the current comparator CMPA for obtaining the comparison signal S1 output by the current comparator CMPA, and the output end of the trigger RS is connected to the OR logic OR, and the trigger signal output by the trigger RS is the current identification signal. In the embodiment of the present application, the output end of the OR logic OR is connected to the control electrode of the control transistor Q2. The charging requirement is whether the voltage of the charging capacitor C2 reaches the high voltage reference value Vref2 and/or whether the charging current I of the charging branch 100 is greater than the preset current value Iref. Therefore, the level signal output by the OR logic OR is the charging control signal Sq2.

As shown in FIG. 12 and FIG. 13, in the embodiment of the present application, since the current comparator CMPA outputs a high level signal when the charging current I is greater than the preset current value Iref, the trigger RS is an RS trigger, the reset end of the trigger RS is connected to the switching power supply chip PWM, and the set end of the trigger RS is connected to the output end of the current comparator CMPA. A not gate NOT1 is provided between the trigger RS and the switching power supply chip PWM. When the control signal SW output by the switching power supply chip PWM is high, under the action of the not gate NOT1, a low level signal is input to the reset end of the trigger RS. At this time, if the comparison signal S1 output by the current comparator CMPA is high, the current identification signal output by the trigger RS is a high level signal, and one input end of the OR logic OR obtains a high level signal. Therefore, the OR logic OR outputs a high level signal, and the control transistor Q2 is turned on. When the control signal SW output by the switching power supply chip PWM maintains a high-level output, even if the set end of the trigger RS transitions to a low level signal, the trigger signal output by the output end of the trigger RS is still high. When the control signal SW output by the switching power supply chip PWM transitions to a low level signal, the output of the output end of the trigger RS transitions to a low level signal, and the control transistor Q2 is turned off.

As shown in FIG. 12 and FIG. 13, since the voltage-resistant switching transistor Q1 adopts a depletion gallium nitride transistor, it is in the on state under normal conditions. Therefore, when the control transistor Q2 is turned off and the charging switching transistor Q3 is turned on, the charging circuit is turned on and the charging capacitor C2 starts to charge. When the charging current I reaches the preset current value Iref, the control transistor Q2 is turned on, and at this time the source of the voltage-resistant switching transistor Q1 is pulled down to ground, and the source voltage of the voltage-resistant switching transistor Q1 is close to 0V, so that the source voltage of the voltage-resistant switching transistor Q1 is lower than the voltage of the charging capacitor C2, the charging circuit is disconnected, and the charging capacitor C2 stops charging. At this time, the primary circuit is turned on and the primary coil N1 stores energy. When the control transistor Q2 is turned on, the unidirectional conducting transistor D2 is reversely turned off, the charging branch 100 is turned off, and the charging capacitor C2 stops charging, and it will not discharge to the ground through the charging switching transistor Q3 and the control transistor Q2.

The self-powering principle of the self-powered circuit of the switching power supply based on the continuous conduction mode in an embodiment of the present application is as follows: when the voltage comparator CMPV detects that the voltage signal VCC is less than the low voltage reference value Vref1, the voltage comparator CMPV outputs a low voltage supplementary power signal, and the low voltage supplementary power signal is a high level signal. At this time, under the action of the NOT logic NOT2, the first conductive element controls the low voltage reference circuit to be disconnected from the voltage comparator CMPV, and the second conductive element controls the high voltage reference circuit to be connected to the voltage comparator CMPV. At this time, the voltage comparator CMPV compares the voltage signal VCC with the high voltage reference value Vref2. When the voltage signal VCC is lower than the high voltage reference value Vref2, the voltage comparator CMPV outputs a charging signal, and the charging signal is a high level signal.

When the control signal SW output by the switching power supply chip PWM is a low level signal, if the voltage sampling feedback device 310 outputs a low voltage supplementary power signal, the switching power supply chip PWM prolongs the duration of the control signal SW being at a low level, and the switching power supply is switched from continuous conduction mode to discontinuous conduction mode, so that the energy of the coil can be fully discharged. At the same time, the voltage sampling feedback device 310 samples the voltage of the secondary coil N2 and transmits the sampling signal CS to the switching power supply chip PWM. When the switching power supply chip PWM detects that the sampling signal CS is a resonant voltage, the switching power supply chip PWM outputs a high level signal.

When the switching power supply chip PWM outputs a high level signal, both input terminals of the first AND logic AND1 are high level signal inputs, so the first AND logic AND1 outputs a high level signal, the charging switching transistor Q3 is turned on, the charging circuit is turned on, and the charging capacitor C2 starts to charge. At the same time, the current sampler 210 starts to sample the current of the charging circuit and outputs a sampling signal CS to the current comparator CMPA. When the sampling signal CS does not reach the preset current value Iref, if the voltage signal VCC obtained by the voltage comparator CMPV is greater than the high voltage reference value Vref2, the voltage comparator CMPV outputs a full power signal, and the full power signal is a low level signal. At this time, one input end of the first AND logic AND1 is a low-level input, so that the first AND logic AND1 outputs a low level signal, the charging switching transistor Q3 is turned off, the charging circuit is disconnected, and the charging capacitor C2 stops charging. The two input ends of the second AND logic AND2 are both high-level inputs, so that the end of the OR logic OR connected to the second AND logic AND2 is a high-level input, so the OR logic OR outputs a high level signal, the control transistor Q2 is turned on, the primary circuit is turned on, and the primary coil N1 stores energy.

When the sampling signal CS is greater than the preset current value Iref, the current comparator CMPA outputs a high level signal to the trigger RS. At this time, the set end of the trigger RS is a high-level input, and the reset end is a low-level input. According to the characteristics of the RS trigger, when the control signal SW output by the switching power supply chip PWM does not transition to a low level, the trigger signals output by the trigger RS are all high level signals. If the voltage signal VCC obtained by the voltage comparator CMPV is still less than the high voltage reference value Vref2, the output of the voltage comparator CMPV is still a charging signal, and the charging signal is a high level. At this time, the charging switching transistor Q3 remains turned on. Since one end of the OR logic OR connected to the trigger RS is a high-level input, the OR logic OR outputs a high level signal, and the control transistor Q2 is turned on, so that the source of the voltage-resistant switching transistor Q1 is pulled down to ground. Therefore, the source voltage of the voltage-resistant switching transistor Q1 is lower than the voltage of the charging capacitor C2, the charging circuit is disconnected, and the charging capacitor C2 stops charging. At this time, the primary circuit is turned on, and the primary coil N1 stores energy. During the next time when the switching power supply chip PWM outputs a low level signal, since the comparator outputs a high level signal, the switching power supply chip PWM will still prolong the duration of the control signal SW being a low level signal, so that the switching power supply works in a discontinuous conduction mode, ensuring that when the next switching cycle arrives, the secondary coil N2 is completely discharged and the charging capacitor C2 can be charged from a current value of 0.

When the switching power supply outputs a low level signal, the first AND logic AND1 outputs a low level signal, the charging switching transistor Q3 is turned off, the second AND logic AND2 outputs a low level signal, and the delay TD also outputs a low level signal, so that the OR logic OR outputs a low level signal, and the control transistor Q2 is turned off. At this time, the primary circuit is disconnected, and the secondary coil N2 supplies power to the load.

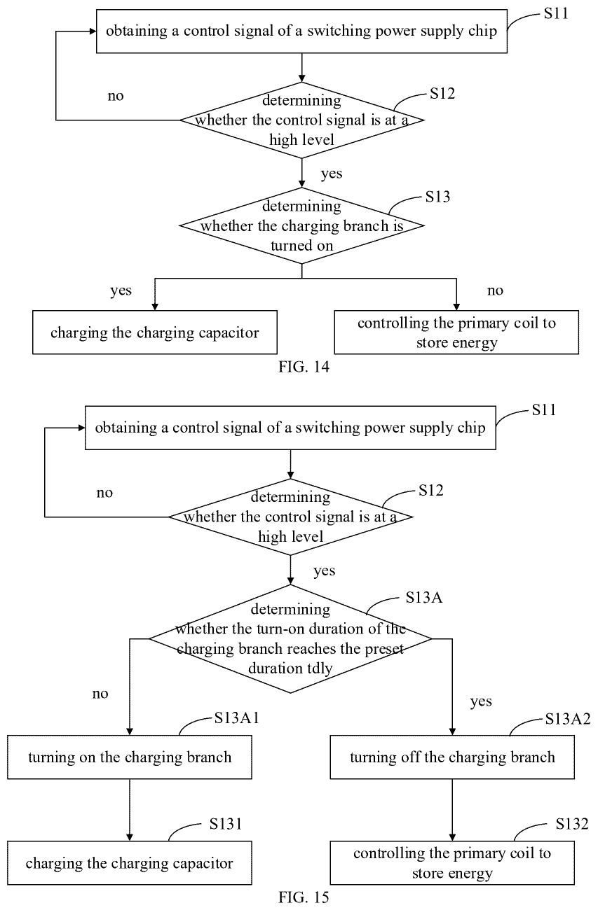

The embodiment of the present application also discloses a method for self-powering a switching power supply of a self-powered circuit based on DCM. As shown in FIG. 14, the self-powering method includes the following steps:
S11, obtaining a control signal of a switching power supply chip.

Specifically, a control signal output by the switching power supply chip is obtained, and when the control signal is a high level signal, the primary coil of the switching power supply is turned on. When the control signal is a low level signal, the primary coil transfers energy to the secondary coil, and the secondary coil supplies power to the load.
S12, determining whether the control signal is at a high level; if yes, executing the following steps; if no, executing S11, reobtaining the control signal of the switch power chip.
S13, determining whether the charging branch is turned on; if yes, executing S131, charging the charging capacitor; if no, executing S132, controlling the primary coil to store energy.

Specifically, the control signal SW has two states: high level and low level. When the control signal SW is at a low level, the primary coil N1 will not be turned on, so the charging branch is always in a disconnected state. When the control signal SW is at a high level, the charging branch is turned on.

When the control signal SW is at a high level, the charging switching transistor Q3 will be turned on to enable the charging circuit to charge the charging capacitor C2. When the charging capacitor C2 reaches the corresponding charging requirement, the control transistor Q2 will be turned on to disconnect the charging circuit, stop charging the charging capacitor C2, and turn on the primary circuit to store energy in the primary coil N1.

In an embodiment, as shown in FIG. 15, the method includes S11, S12 and S13, and the S13, determining whether the charging branch is turned on specifically includes the following steps
S13A, determining whether the turn-on duration of the charging branch 100 reaches the preset duration tdly; if no, executing S13A1, turning on the charging branch, and then executing S131; if yes, executing S13A2, turning off the charging branch, and then executing S132.

Specifically, in the embodiment of the present application, the charging requirement of the charging capacitor C2 is the charging time, and the delay TD is configured to time the duration of the control signal SW being at a high level, and the delay TD is preset with a preset duration tdly. The delay TD is triggered at a high level, that is, when the control signal SW output by the switching power supply chip PWM is at a high level, the delay TD starts to start timing. When the control signal SW output by the switching power supply chip PWM is at a high level, the charging switching transistor Q3 is turned on first, and the charging circuit is turned on to charge the charging capacitor C2. At this time, the delay TD counts the on-time of the charging circuit. When the timing duration of the delay TD reaches the preset duration tdly, the control transistor Q2 is turned on, the source of the voltage-resistant switching transistor Q1 is grounded, the charging circuit is disconnected, the charging capacitor C2 stops charging, the primary circuit is turned on, and the primary coil N1 starts to store energy until the control signal SW output by the switching power supply chip PWM transitions from a high level to a low level, the charging circuit and the primary circuit are both disconnected, and the secondary coil N2 supplies power to the load.

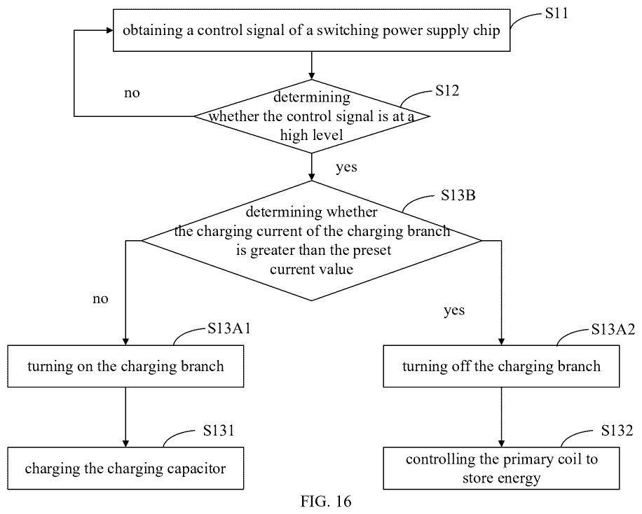

In another embodiment, as shown in FIG. 16, the method includes S11, S12 and S13, and the S13, determining whether the charging branch is turned on includes the following steps:
S13B, determining whether the charging current of the charging branch is greater than the preset current value; if no, executing S13A1, turning on the charging branch, and then executing S131; if yes, executing S13A2, turning off the charging branch, and then executing S132.

Specifically, in the embodiment of the present application, the charging requirement of the charging capacitor C2 is the value of the charging current I, the current sampler 210 samples the charging current I of the charging circuit, and the comparison controller 220 is configured to compare the value of the charging current I, which is preset with a preset current value Iref. When the control signal SW output by the switching power supply chip PWM is at a high level, the charging switching transistor Q3 is turned on first, and the charging branch 100 is turned on to charge the charging capacitor C2. The current sampler 210 samples the charging current I of the charging circuit and transmits the sampling signal CS to the comparison controller 220. The comparison controller 220 compares the sampling signal CS with the preset current value Iref. As the charging time increases, the charging current I gradually increases, that is, the sampling signal CS gradually increases. When the sampling signal CS is greater than the preset current value Iref, the control transistor Q2 is turned on, the source of the voltage-resistant switching transistor Q1 is grounded, the charging circuit is disconnected, the charging capacitor C2 stops charging, the primary circuit is turned on, and the primary coil N1 starts to store energy until the control signal SW output by the switching power supply chip PWM transitions from a high level to a low level, then the charging circuit and the primary circuit are both disconnected, and the secondary coil N2 supplies power to the load.

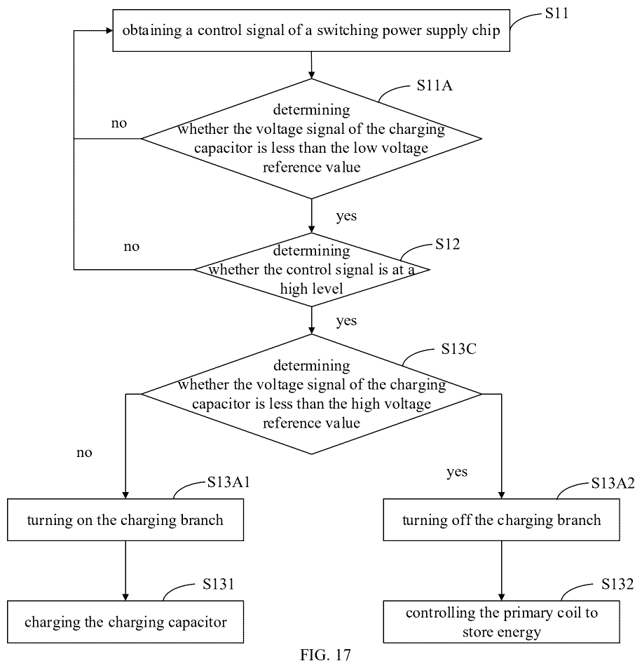

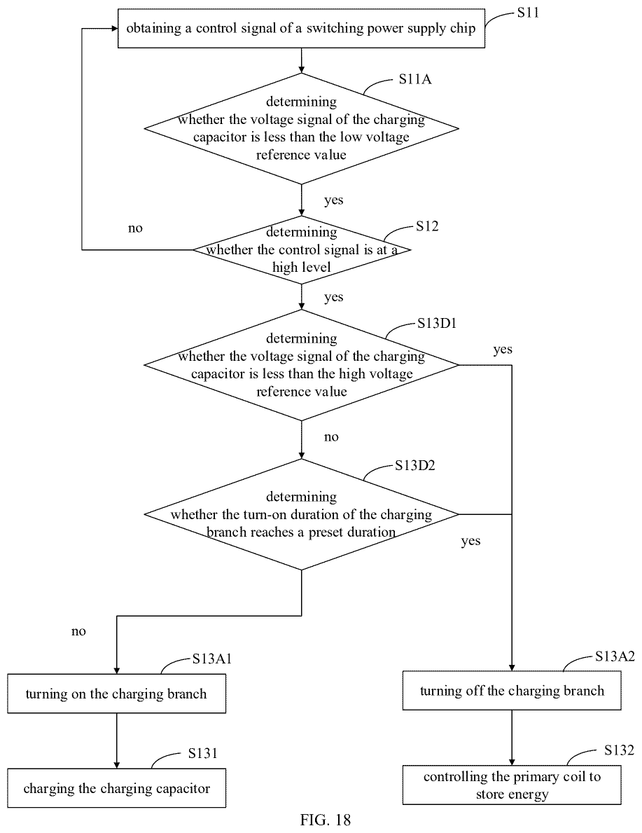

In another embodiment, as shown in FIG. 17, before S13, determining whether the charging branch is turned on, it is also necessary to determine whether the charging capacitor needs to be recharged, which specifically includes the following steps:
S11A, determining whether the voltage signal of the charging capacitor is less than the low voltage reference value; if yes, the charging capacitor needs to be recharged, and executing S12; if no, the charging capacitor does not need to be recharged, and then executing S11.
S12, determining whether the control signal is at a high level; if yes, executing S13C; if no, executing S11.
S13C, determining whether the voltage signal of the charging capacitor is less than the high voltage reference value; if yes, executing S13A2, turning on the charging branch, and then executing S132; if no, executing S13A1, turning off the charging branch, and then executing S131.

Specifically, in the embodiment of the present application, the charging requirement of the charging capacitor C2 is the value of the voltage signal VCC of the charging capacitor C2. The voltage sampler 230 is configured to sample the voltage signal VCC of the charging capacitor C2 and compare the voltage signal VCC with its preset reference voltage. The reference voltage includes a low voltage reference value Vref1 and a high voltage reference value Vref2. The low voltage reference value Vref1 is less than the high voltage reference value Vref2.

The voltage sampler 230 obtains the voltage signal VCC of the charging capacitor C2 and compares the voltage signal VCC with the low voltage reference value Vref1, when the voltage signal VCC of the charging capacitor C2 is greater than the low voltage reference value Vref1, it means that the charging capacitor C2 does not need to be supplemented with power. When the control signal SW output by the switching power supply chip PWM is at a high level, the charging capacitor C2 does not need to be supplemented with power. At this time, the charging switching transistor Q3 remains cut off, the charging circuit is not turned on, the control transistor Q2 is turned on, the primary circuit is turned on, and the primary coil N1 stores energy.

When the voltage signal VCC of the charging capacitor C2 is less than the low voltage reference value Vref1, it indicates that the charging capacitor C2 needs to be recharged. At the same time, the voltage sampler 230 compares the voltage signal VCC with the high voltage reference value Vref2. When the control signal SW output by the switching power supply chip PWM is at a high level, the charging switching transistor Q3 is turned on and the control transistor Q2 is turned off. At this time, the charging circuit is turned on and the charging capacitor C2 is charged. When the voltage signal VCC is greater than the high voltage reference value Vref2, it indicates that the charging capacitor C2 is fully charged. At this time, the voltage sampler 230 compares the voltage signal VCC with the low voltage reference value Vref1 again, the charging switching transistor Q3 is turned off, the charging circuit is disconnected, the charging capacitor C2 stops charging, the control transistor Q2 is turned on, the primary circuit is turned on, and the primary coil N1 stores energy.

In another embodiment, as shown in FIG. 18, before the step of determining whether the charging branch 100 is turned on, it is also necessary to determine whether the charging capacitor C2 needs to be recharged, which specifically includes the following steps:
S11A, determining whether the voltage signal VCC of the charging capacitor C2 is less than the low voltage reference value Vref1; if yes, the charging capacitor C2 needs to be recharged, and the following steps are performed; if no, the charging capacitor C2 does not need to be recharged;
S13D1, determining whether the voltage signal of the charging capacitor is less than the high voltage reference value;
S13D2, determining whether the turn-on duration of the charging branch reaches a preset duration; and
S13D3, if the judgment results of S13D1 and S13D2 are all negative, executing S13A1, turning on the charging branch 100, and then executing S131; if any one of the judgment results of S13D1 and S13D2 is positive, executing S13A2, turning off the charging branch 100, and then executing S132.

Specifically, in the embodiment of the present application, the charging requirements of the charging capacitor C2 are the voltage signal VCC of the charging capacitor C2 and the charging time. When either the voltage signal or the charging time of the charging capacitor C2 meets the requirements, the charging capacitor C2 will no longer continue to charge. The voltage sampler 230 is configured to sample the voltage signal VCC of the charging capacitor C2, and compare the voltage signal VCC with its preset reference voltage. The reference voltage includes a low voltage reference value Vref1 and a high voltage reference value Vref2. The low voltage reference value Vref1 is less than the high voltage reference value Vref2.

The voltage sampler 230 obtains the voltage signal VCC of the charging capacitor C2 and compares the voltage signal VCC with the low voltage reference value Vref1, when the voltage signal VCC of the charging capacitor C2 is greater than the low voltage reference value Vref1, it means that the charging capacitor C2 does not need to be supplemented with power. When the control signal SW output by the switching power supply chip PWM is at a high level, the charging capacitor C2 does not need to be supplemented with power. At this time, the charging switching transistor Q3 remains cut off, the charging circuit is not turned on, the control transistor Q2 is turned on, the primary circuit is turned on, and the primary coil N1 stores energy.

When the voltage signal VCC of the charging capacitor C2 is less than the low voltage reference value Vref1, it means that the charging capacitor C2 needs to be recharged. At the same time, the voltage sampler 230 compares the voltage signal VCC with the high voltage reference value Vref2. When the control signal SW output by the switching power supply chip PWM is at a high level, the charging switching transistor Q3 is turned on and the control transistor Q2 is turned off. At this time, the charging circuit is turned on and the charging capacitor C2 is charged.

During the preset duration dtly, when the voltage signal VCC is greater than the high voltage reference value Vref2, it indicates that the charging capacitor C2 is fully charged. At this time, the voltage sampler 230 compares the voltage signal VCC with the low voltage reference value Vref1 again, the charging switching transistor Q3 is turned off, the charging circuit is disconnected, the charging capacitor C2 stops charging, the control transistor Q2 is turned on, the primary circuit is turned on, and the primary coil N1 stores energy.

If the timing duration of the delay TD reaches the preset duration dtly, and the voltage signal VCC is still less than the high voltage reference value Vref2, the delay TD outputs a high level signal. At this time, the end of the OR logic OR connected to the delay TD inputs a high level signal and the charging control signal Sq2 output by the OR logic OR is a high level signal. At this time, the control transistor Q2 is turned on, the source of the voltage-resistant switching transistor Q1 is grounded, the charging branch is disconnected, and the charging capacitor C2 stops charging.

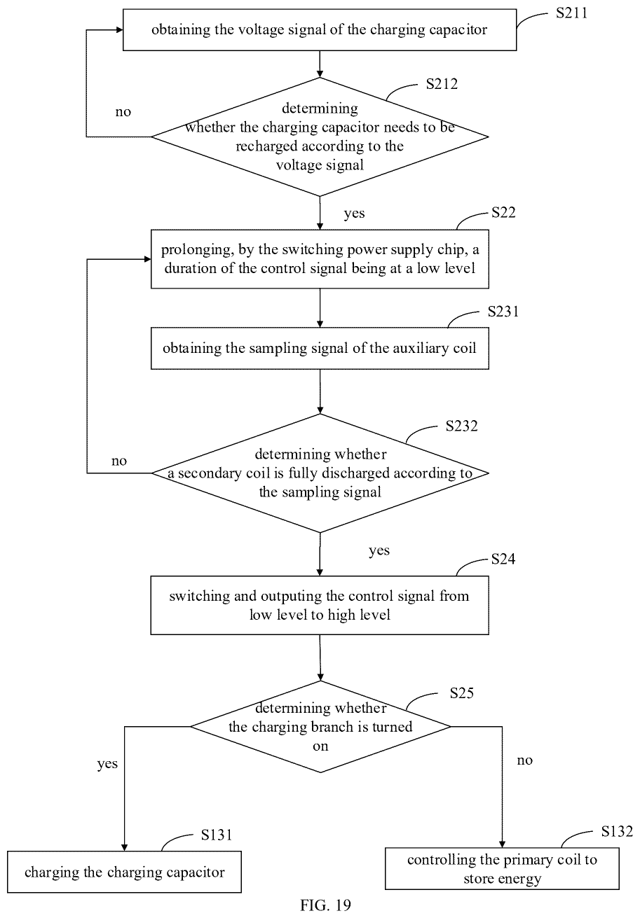

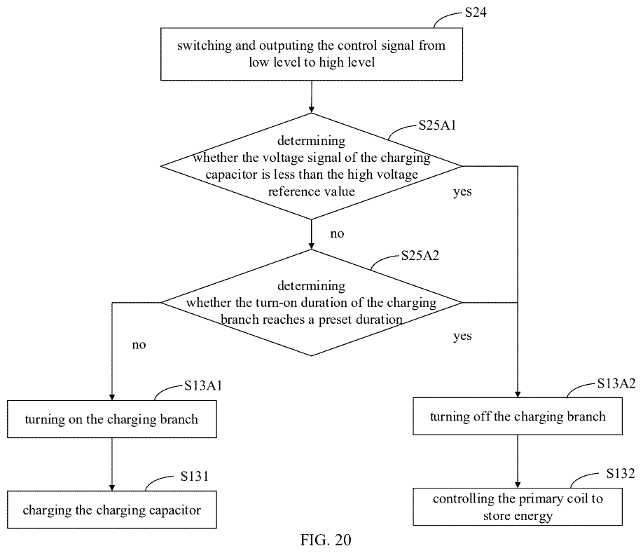

The embodiment of the present application also discloses a method for self-powering a switching power supply of a self-powered circuit based on CCM. As shown in FIG. 19, the self-powering method includes the following steps:
S211, obtaining the voltage signal of the charging capacitor.
S212, determining whether the charging capacitor needs to be recharged according to the voltage signal; if yes, performing the following steps; if no, continuing to executing S211, obtaining the voltage signal of the charging capacitor.

Specifically, the voltage sampler 230 is preset with a low voltage reference value Vref1 and a high voltage reference value Vref2, and the low voltage reference value Vref1 is less than the high voltage reference value Vref2. The voltage sampler 230 is configured to obtain the voltage signal VCC of the charging capacitor C2 and compare the voltage signal VCC with the low voltage reference value Vref1 and the high voltage reference value Vref2, and then output a judgment signal S2. The judgment signal S2 includes a low voltage supplementary power signal, a charging signal, and a full power signal. When the voltage signal VCC is less than the low voltage reference value Vref1, a low voltage supplementary power signal is output. When the voltage signal VCC is greater than the low voltage reference value Vref1 and less than the high voltage reference value Vref2, a charging signal is output. When the voltage signal VCC is greater than the high voltage reference value Vref2, a full power signal is output. When the judgment signal S2 output by the voltage sampler 230 is a low voltage supplementary power signal or a charging signal, it means that the charging capacitor C2 needs to be supplemented.
S22, prolonging, by the switching power supply chip, a duration of the control signal being at a low level.
S231, obtaining the sampling signal of the auxiliary coil.
S232, determining whether a secondary coil is fully discharged according to the sampling signal; if yes, performing the following steps; if no, continuing to executing S22.

Specifically, the switching power supply chip PWM prolongs the duration of the control signal SW being at a low level, so that the duration of the discharge of the secondary coil N2 is increased, thereby converting the switching power supply from a continuous conduction mode to a discontinuous conduction mode. The voltage sampling feedback device 310 is provided between the auxiliary coil N3 and the switching power supply chip PWM, and samples the voltage on the auxiliary coil N3 to obtain a sampling signal CS. The switching power supply chip PWM receives the sampling signal CS and determines whether the secondary coil N2 is fully discharged through the sampling signal CS. If the secondary coil N2 is fully discharged, it means that the switching power supply is converted from a continuous conduction mode to a discontinuous conduction mode. If the secondary coil N2 is not fully discharged, the duration of the control signal SW being at a low level is further extended to convert the switching power supply from a continuous conduction mode to a discontinuous conduction mode.
S24, switching and outputting the control signal from low level to high level.
S25, determining whether the charging branch is turned on; if yes, executing S131, charging the charging capacitor; if no, executing S132, controlling the primary coil to store energy.

Specifically, when the charging capacitor C2 needs to be recharged and the secondary coil N2 is fully discharged, the control signal SW output by the switching power supply chip PWM changes from a low level to a high level. At this time, the charging switching transistor Q3 will be turned on first to enable the charging circuit to charge the charging capacitor C2. When the charging capacitor C2 is fully charged, that is, when the voltage sampling feedback device 310 outputs the judgment signal S2 that is fully charged, the charging switching transistor Q3 is turned off, so that the charging circuit is disconnected and the charging capacitor C2 stops charging. At the same time, the control transistor Q2 is turned on, the primary circuit is turned on, and the primary coil N1 is stored with energy.

In an embodiment, as shown in FIG. 20, determining whether the charging branch 100 is turned on specifically includes the following steps:
S25A1, determining whether the voltage signal of the charging capacitor is less than the high voltage reference value;
S25A2, determining whether the turn-on duration of the charging branch reaches a preset duration; if the judgment results of S25A1 and S25A2 are negative, executing S13A1, turning on the charging branch, and then executing S131; if any one of the judgment results of S25A1 and S25A2 is positive, executing S13A2, turning off the charging branch, and then executing S132.

Specifically, in the embodiment of the present application, the charging requirement of the charging capacitor C2 is the value of the voltage signal VCC and/or the charging time of the charging capacitor C2. When the voltage signal VCC of the charging capacitor C2 is less than the low voltage reference value Vref1, then when the next switching cycle arrives, the charging circuit is preferentially turned on to replenish the charging capacitor C2 until the charging of the charging capacitor C2 is completed. That is, the voltage signal VCC of the charging capacitor C2 is greater than the high voltage reference value Vref2, but during the charging process of the charging capacitor C2 the energy storage of the primary coil N1 is affected. In order to prevent the charging time of the charging capacitor C2 from being too long, resulting in the energy storage of the primary coil N1 being unable to meet the normal operation of the switching power supply, the conduction of the charging circuit is also controlled by the delay TD.

The delay TD is triggered by a high level and is configured to time the duration of the control signal SW being at a high level. It is preset with a preset duration tdly. When the control signal SW output by the switching power supply chip PWM is at a high level, the delay TD starts timing, at which time the charging switching transistor Q3 is turned on first, and the charging capacitor C2 is charged. Within the preset duration tdly, if the voltage signal VCC of the charging capacitor C2 is less than the high voltage reference value Vref2, it means that the charging capacitor C2 still needs to be supplemented, and the charging circuit remains turned on. Within the preset duration tdly, if the voltage signal VCC of the charging capacitor C2 is greater than the high voltage reference value Vref2, it means that the charging capacitor C2 is fully charged, at this time the charging switching transistor Q3 is turned off, the charging circuit is disconnected, and the charging capacitor C2 stops charging. If the timing duration of the delay TD reaches the preset duration tdly, and the voltage signal VCC of the charging capacitor C2 is still less than the high voltage reference value Vref2, the control transistor Q2 is turned on, the source of the voltage-resistant switching transistor Q1 is grounded, the charging circuit is disconnected, the charging capacitor C2 stops charging, the primary circuit is turned on, and the primary coil N1 starts to store energy until the control signal SW output by the switching power supply chip PWM transitions from a high level to a low level, then the charging circuit and the primary circuit are both disconnected, and the secondary coil N2 supplies power to the load.

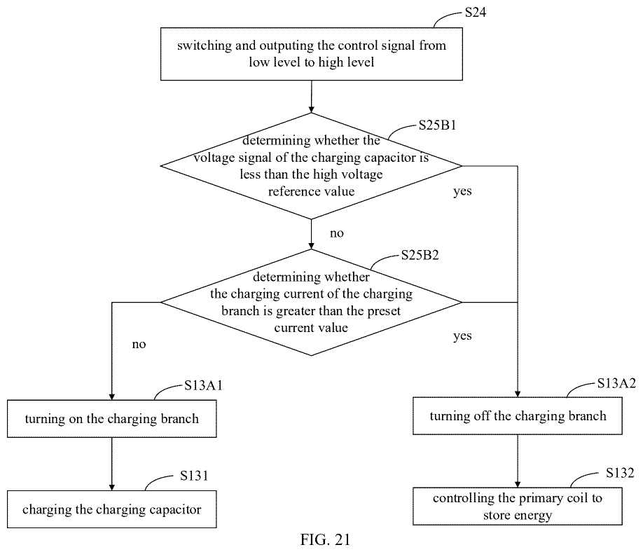

In another embodiment, as shown in FIG. 21, the step of determining whether the charging branch 100 is turned on includes the following steps:
S25B1, determining whether the voltage signal of the charging capacitor is less than the high voltage reference value;
S25B2, determining whether the charging current of the charging branch is greater than the preset current value; if the judgment results of S25B1 and S25B2 are negative, executing S13A1, turning on the charging branch, and then executing S131; if any one of the judgment results of S25B1 and S25B2 is positive, executing S13A2, turning off the charging branch, and then executing S132.

Specifically, in the embodiment of the present application, the charging requirement of the charging capacitor C2 is the value of the voltage signal VCC and/or the value of the charging current I of the charging capacitor C2. After the charging circuit is turned on, as the turn-on duration increases, the charging current I of the charging capacitor C2 gradually increases. In order to ensure that the charging capacitor C2 is charged with a small current and thus reduce the area of the self-powered circuit, the conduction of the charging circuit is also controlled by the value of the charging current I.

The current sampler 210 is provided in the charging circuit, and is configured to detect the charging current I of the charging circuit and output the sampling signal CS. The comparison controller 220 is preset with a preset current value Iref, and is configured to receive the sampling signal CS and compare the sampling signal CS with the preset current value Iref. When the control signal SW output by the switching power supply chip PWM is at a high level, the charging switching transistor Q3 is turned on first, and the charging circuit is turned on to charge the charging capacitor C2. The current sampler 210 samples the charging current I of the charging capacitor C2 and transmits the sampling signal CS to the comparison controller 220. The comparison controller 220 compares the sampling signal CS with the preset current value Iref. As the turn-on duration increases, the charging current I gradually increases.

When the sampling signal CS is less than the preset current value Iref, if the voltage signal VCC of the charging voltage is less than the high voltage reference value Vref2, it means that the charging capacitor C2 still needs to be supplemented, and the charging circuit remains turned on. If the voltage signal VCC of the charging capacitor C2 is greater than the high voltage reference value Vref2, it means that the charging capacitor C2 is fully charged, and the charging switching transistor Q3 is cut off, the charging circuit is disconnected, and the charging capacitor C2 stops charging. When the sampling signal CS is greater than the preset current value Iref, the voltage signal VCC of the charging capacitor C2 is still less than the high voltage reference value Vref2, then the control transistor Q2 is turned on, the source of the voltage-resistant switching transistor Q1 is grounded, the charging circuit is disconnected, the charging capacitor C2 stops charging, the primary circuit is turned on, and the primary coil N1 starts to store energy until the control signal SW output by the switching power supply chip PWM transitions from a high level to a low level, the charging circuit and the primary circuit are both disconnected, and the secondary coil N2 supplies power to the load.

The embodiment of the present application also discloses a self-powered chip based on a discontinuous conduction mode switching power supply. The self-powered chip integrates the self-powered circuit disclosed in the above embodiment, including a voltage-resistant switching transistor Q1, a charging branch, and a charging control unit 200, so that the charging capacitor C2 draws power from the primary coil N1, and adaptively replenishes power for the charging capacitor C2 from a small current (0 A) during the switching cycle. The self-powered chip is suitable for a flyback switching power supply, by using a depletion gallium nitride transistor as a voltage-resistant switching transistor Q1, and by using its working characteristics to take power from the source end, which can ensure that the self-powered chip only works in a low-voltage state, thereby reducing the complexity of the chip, and reducing the resistant voltage requirements of the internal devices of the chip. That is, the charging switching transistor Q3, the control transistor Q2, and the unidirectional conducting transistor D2 can be designed with devices with a lower resistant voltage to save the layout area, thereby reducing the final chip area, improving efficiency, and reducing costs. The voltage-resistant switching transistor Q1 and the charging capacitor C2 can not only be integrated in the self-powered chip, but also be independent of the self-powered chip and set separately. Similarly, the self-powered chip and the switching power supply chip PWM can be further integrated into a power control chip to improve the chip integration.

The embodiment of the present application also discloses a self-powered chip based on a continuous conduction mode switching power supply. The self-powered chip integrates the self-powered circuit disclosed in the above embodiment, including a voltage-resistant switching transistor Q1, a charging branch 100, a mode switching unit 300 and a charging control unit 200, so that the charging capacitor C2 can take power from the primary coil N1 sample and detect the voltage of the charging capacitor C2, and introduce a discontinuous conduction mode when the charging capacitor C2 needs to be recharged, so that it can adaptively supplement the charging capacitor C2 from a small current (0 A) during the switching cycle. The self-powered chip is suitable for a flyback switching power supply, by using a depletion gallium nitride transistor as a voltage-resistant switching transistor Q1, and by using its working characteristics to take power from the source end, which can ensure that the self-powered chip only works in a low-voltage state, thereby reducing the complexity of the chip, and reducing the resistant voltage requirements of the internal devices of the chip. That is, the charging switching transistor Q3, the control transistor Q2 and the unidirectional conducting transistor D2 can be designed with devices with a lower resistant voltage to save the layout area, thereby reducing the final chip area, improving efficiency and reducing costs. The voltage-resistant switching transistor Q1 and the charging capacitor C2 can not only be integrated into the self-powered chip, but also be independently provided outside the self-powered chip. Similarly, the self-powered chip and the switching power supply chip PWM can be further integrated into a power control chip to improve the integration of the chip.

The above are only some embodiments of the present application, and the protection scope of the present application is not limited thereto. Therefore, any equivalent changes made according to the structure, shape, and principle of the present application should be included in the protection scope of the present application.

What is claimed is

1. A self-powered circuit based on discontinuous conduction mode (DCM), applied to a flyback switching power supply, comprising:
a voltage-resistant switching transistor;
a charging branch; and
a charging control unit,
wherein the voltage-resistant switching transistor is connected in series between a primary coil and the charging branch, and is configured to obtain a power supply voltage of the primary coil and output a charging voltage for charging the charging branch;
the voltage-resistant switching transistor adopts a depletion gallium nitride transistor, a drain of the voltage-resistant switching transistor is connected to the primary coil, a source of the voltage-resistant switching transistor is connected to the charging branch and the charging control unit, and a gate of the voltage-resistant switching transistor is grounded;
the charging branch comprises a charging capacitor for supplying power to a switching power supply chip and a charging switching transistor for controlling whether the charging capacitor is charged, the charging switching transistor is connected between the charging capacitor and the voltage-resistant switching transistor;
the charging control unit is configured to control whether the charging branch is turned on; and
the charging control unit further comprises a control transistor connected between the voltage-resistant switching transistor and the ground, and the control transistor is provided in parallel with the charging switching transistor and the charging capacitor, and the control transistor is configured to control whether a source of the voltage-resistant switching transistor is grounded.

2. The self-powered circuit based on DCM according to claim 1, wherein the charging branch further comprises a protection resistor and a unidirectional conducting transistor connected in series with the charging switching transistor and the charging capacitor;
the protection resistor is configured to limit a charging current of the charging capacitor to protect the charging capacitor; and
the unidirectional conducting transistor is configured to make current of the charging branch unidirectionally conducted.

3. The self-powered circuit based on DCM according to claim 2, wherein the charging control unit further comprises a delay, the delay is connected between the control transistor and the switching power supply chip and is configured to delay an output of a control signal output by the switching power supply chip.

4. The self-powered circuit based on DCM according to claim 2, wherein the charging control unit further comprises:
a current sampler; and
a comparison controller,
wherein the current sampler is connected in series to the charging branch, and is configured to detect a charging current of the charging branch and output a sampling signal proportional to the charging current;
an input end of the comparison controller is connected to the current sampler and the switching power supply chip, and the comparison controller is configured to receive the sampling signal and a control signal, and an output end of the comparison controller is connected to a control electrode of the control transistor, and the comparison controller is configured to control the control transistor to be turned on or off according to the sampling signal and the control signal;
the comparison controller comprises a current comparator, an AND logic, and a trigger;
one input end of the current comparator is configured to obtain a preset current value, and another input end of the current comparator is connected to the current sampler, and the current comparator is configured to compare whether the charging current of the charging branch exceeds the preset current value, and output a comparison signal;
one input end of the AND logic is connected to the switching power supply chip for obtaining the control signal, and the other input end is connected to the current comparator for obtaining the comparison signal; and an output end of the AND logic is connected to the control electrode of the control transistor for controlling whether the control transistor is turned on;
the trigger is provided between the current comparator and the AND logic;
one input end of the trigger is connected to the current comparator, and the other input end of the trigger is connected to the switching power supply chip for obtaining the comparison signal and the control signal, and an output end of the trigger connected to the AND logic for outputting a trigger signal according to the comparison signal and the control signal; and
a NOT logic is connected between the trigger and the switching power supply chip.

5. The self-powered circuit based on DCM according to claim 2, wherein the charging control unit further comprises:
a voltage sampler; and
a second AND logic;
wherein an input end of the voltage sampler is connected to one end of the charging capacitor, and the voltage sampler is configured to obtain a voltage signal of the charging capacitor and output a judgment signal; an output end of the voltage sampler is connected to a control electrode of the control transistor, and the voltage sampler is configured to control the control transistor to be turned on or off;
the voltage sampler is preset with a high voltage reference value, and in response to that the charging capacitor voltage signal is greater than the high voltage reference value, the voltage sampler controls the control transistor to be turned on;
an input end of the second AND logic is connected to the voltage sampler and the switching power supply chip, and the second AND logic is configured to receive the judgment signal and the control signal, and an output end of the second AND logic is connected to the control electrode of the control transistor, and the second AND logic is configured to control the control transistor to be turned on or off according to the judgment signal and the control signal;
the voltage sampler comprises a voltage comparator, a low voltage reference circuit and a high voltage reference circuit provided at an input end of the voltage comparator, the low voltage reference circuit is configured to provide a low voltage reference value, the high voltage reference circuit is configured to provide a high voltage reference value, and the high voltage reference value is greater than the low voltage reference value; and
a first conductive element is provided between an output end of the voltage comparator and the low voltage reference circuit, and a second conductive element is provided between the output end of the voltage comparator and the high voltage reference circuit, and the first conductive element and the second conductive element have opposite conduction conditions.

6. The self-powered circuit based on DCM according to claim 5, wherein the charging control unit further comprises a first AND logic, an input end of the first AND logic is connected to the voltage sampler, another input end of the first AND logic is connected to the switching power supply chip, and an output end of the first AND logic is connected to a control electrode of the charging switching transistor.

7. The self-powered circuit based on DCM according to claim 5, wherein the charging control unit further comprises a delay and an OR logic;
the delay is preset with a preset duration, and an input end of the delay is connected to the switching power supply chip, and the delay is configured to delay an output of a control signal output by the switching power supply chip; and
an input end of the OR logic is connected to the second AND logic and the delay respectively, and an output end of the OR logic is connected to the control electrode of the control transistor for controlling the control transistor to be turned on or off.

8. A self-powered circuit based on continuous conduction mode (CCM), applied to a flyback switching power supply, comprising:
a voltage-resistant switching transistor;
a charging branch;
a mode switching unit; and
a charging control unit,
wherein the voltage-resistant switching transistor is connected between a primary coil and the charging branch, and is configured to obtain a power supply voltage of the primary coil and output a charging voltage for charging the charging branch;
the voltage-resistant switching transistor adopts a depletion gallium nitride transistor, a drain of the voltage-resistant switching transistor is connected to the primary coil, a source of the voltage-resistant switching transistor is connected to the charging branch and the charging control unit, and a gate of the voltage-resistant switching transistor is grounded;
the charging branch comprises a charging capacitor for supplying power to a switching power supply chip and a charging switching transistor for controlling whether the charging capacitor is charged, the charging switching transistor is connected between the charging capacitor and the voltage-resistant switching transistor;
the mode switching unit is configured to monitor the voltage of the charging capacitor and the voltage of an auxiliary coil, and output a switching signal for adjusting the output of the control signal of the switching power supply chip;
the charging control unit is configured to control whether the charging branch is turned on; and
the charging control unit comprises a control transistor connected between the voltage-resistant switching transistor and the ground, and the control transistor is provided in parallel with the charging switching transistor and the charging capacitor, and the control transistor is configured to control whether a source of the voltage-resistant switching transistor is grounded.

9. The self-powered circuit based on CCM according to claim 8, wherein the charging branch further comprises a protection resistor and a unidirectional conducting transistor connected in series with the charging switching transistor and the charging capacitor;
the protection resistor is configured to limit a charging current of the charging capacitor to protect the charging capacitor;
the unidirectional conducting transistor is configured to make current of the charging branch unidirectionally conducted;
the mode switching unit comprises a voltage sampler and a sampling feedback device;
the voltage sampler is preset with a low voltage reference value, and the voltage sampler is configured to obtain a voltage signal of the charging capacitor, compare the voltage signal with the low voltage reference value, and output a judgment signal; and
the voltage sampling feedback device is provided between the auxiliary coil and the switching power supply chip, and samples a voltage on the auxiliary coil to obtain a sampling signal, the switching power supply chip is configured to control whether it is necessary to prolong duration of the control signal being at a low level according to the sampling signal and the judgment signal to convert the switching power supply from a continuous conduction mode to a discontinuous conduction mode.

10. The self-powered circuit based on CCM according to claim 9, wherein the voltage sampler comprises a voltage comparator, a low voltage reference circuit and a high voltage reference circuit provided at an input end of the voltage comparator;
the low voltage reference circuit is configured to provide a low voltage reference value, the high voltage reference circuit is configured to provide a high voltage reference value, and the high voltage reference value is greater than the low voltage reference value;
a first conductive element is provided between an output end of the voltage comparator and the low voltage reference circuit, and a second conductive element is provided between the output end of the voltage comparator and the high voltage reference circuit, and the first conductive element and the second conductive element have opposite conduction conditions; and
a first AND logic is provided between the voltage comparator and the charging switching transistor, an input end of the first AND logic is respectively connected to the voltage comparator and the switching power supply chip, and an output end of the first AND logic is connected to a control electrode of the charging switching transistor.

11. The self-powered circuit based on CCM according to claim 9, wherein the charging control unit further comprises:
a delay;
a second AND logic; and
an OR logic,
wherein the delay is connected between a control transistor and the switching power supply chip, and is configured to delay an output of a control signal output by the switching power supply chip;
an input end of the second AND logic is connected to the voltage sampler and the switching power supply chip, and an output end of the second AND logic is coupled to the control transistor, the second AND logic is configured to receive the judgment signal and the control signal, and output a voltage identification signal to the control transistor according to the judgment signal and the control signal; and
an input end of the OR logic is respectively connected to an output end of the delay and an output end of the second AND logic, the OR logic is configured to obtain a control signal delayed by the delay and a voltage identification signal, an output end of the OR logic is connected to a control electrode of the control transistor, and the OR logic is configured to control the control transistor to be turned on or off.

12. The self-powered circuit based on CCM according to claim 9, wherein the charging control unit further comprises:
a current sampler;
a comparison controller;
a second AND logic; and
an OR logic,
wherein the current sampler is connected in series to the charging branch, and is configured to detect a charging current of the charging branch and output a sampling signal proportional to the charging current;
an input end of the comparison controller is connected to the current sampler and the switching power supply chip, the comparison controller is configured to receive the sampling signal and the control signal, and output a current identification signal according to the sampling signal and the control signal;
an input end of the second AND logic is connected to the voltage sampler and the switching power supply chip, an output end of the second AND logic is coupled to the control transistor, the second AND logic is configured to receive the judgment signal and the control signal, and output a voltage identification signal to the control transistor according to the judgment signal and the control signal;
an input end of the OR logic is respectively connected to an output end of the comparison controller and the output end of the second AND logic, the OR logic is configured to obtain the current identification signal and a voltage identification signal, an output end of the OR logic is connected to a control electrode of the control transistor, and the OR logic is configured to control the control transistor to be turned on or off;
the comparison controller comprises a current comparator and a trigger;
one input end of the current comparator obtains a preset current value, and the other input end of the current comparator is connected to the current sampler, and the current comparator is configured to compare whether the charging current of the charging branch exceeds the preset current value, and output a comparison signal; and
one input end of the trigger is connected to the switching power supply chip for obtaining the control signal, and the other input end of the trigger is connected to an output end of the current comparator for obtaining the comparison signal, and an output end of the trigger is connected to the OR logic.

13. A method for self-powering a switching power supply of the self-powered circuit based on DCM according to claim 1, comprising:
obtaining a control signal of the switching power supply chip;
determining whether the control signal is at a high level;
in response to that the control signal is at the high level, determining whether the charging branch is turned on;
in response to that the charging branch is turned on, charging the charging capacitor,
in response to that the charging branch is turned off, controlling the primary coil to store energy; or
in response to that the control signal is not at the high level, reobtaining the control signal.

14. The method according to claim 13, the determining whether the charging branch is turned on comprises:
determining whether turn-on duration of the charging branch reaches a preset duration;
in response to that the turn-on duration of the charging branch does not reach the preset duration, turning on the charging branch; or
in response to that the turn-on duration of the charging branch reaches the preset duration, turning off the charging branch.

15. The method according to claim 13, wherein the determining whether the charging branch is turned on comprises:
determining whether the charging current of the charging branch is greater than the preset current value;
in response to that the charging current of the charging branch is not greater than the preset current value, turning on the charging branch; or
in response to that the charging current of the charging branch is greater than the preset current value, turning off the charging branch.

16. The method according to claim 13, wherein before the determining whether the charging branch is turned on, the method further comprises:
in response to a determination that the voltage signal of the charging capacitor is less than the low voltage reference value, determining whether the voltage signal of the charging capacitor is less than the high voltage reference value;
in response to that the voltage signal of the charging capacitor is less than the low voltage reference value, turning on the charging branch;
in response to that the voltage signal of the charging capacitor is not less than the low voltage reference value, turning off the charging branch; and
before the determining whether the charging branch is turned on, the method further comprises:
in response to determining that the voltage signal of the charging capacitor is less than the low voltage reference value, determining whether the voltage signal of the charging capacitor is less than the high voltage reference value, and whether turn-on duration of the charging branch reaches a preset duration;
in response to that the voltage signal of the charging capacitor is not less than the high voltage reference value and the turn-on duration of the charging branch does not reach the preset duration, turning on the charging branch;
in response to that the voltage signal of the charging capacitor is less than the high voltage reference value and/or the turn-on duration of the charging branch reaches the preset duration, turning off the charging branch.

17. A method for self-powering a switching power supply of the self-powered circuit based on CCM according to claim 8, comprising:
obtaining the voltage signal of the charging capacitor, and determining whether the charging capacitor needs to be recharged according to the voltage signal;
in response to that the charging capacitor needs to be recharged, prolonging, by the switching power supply chip, a duration of the control signal being at a low level;
obtaining the sampling signal of the auxiliary coil, and determining whether a secondary coil is fully discharged according to the sampling signal; in response to that the secondary coil is fully discharged, switching and outputting the control signal from low level to high level; determining whether the charging branch is turned on; in response to that the charging branch is turned on, charging the charging capacitor, and in response to that the charging branch is not turned on, controlling the primary coil to store energy; and in response to that the secondary coil is not fully discharged, continuing to prolong the duration of the control signal being at the low level; or
in response to that the charging capacitor does not need to be recharged, continuing to obtain the voltage signal.

18. The method according to claim 17, the determining whether the charging branch is turned on comprises:
determining whether the voltage signal of the charging capacitor is less than the high voltage reference value;
determining whether turn-on duration of the charging branch reaches the preset duration;
in response to that the voltage signal of the charging capacitor is not less than the high voltage reference value and the turn-on duration of the charging branch does not reach the preset duration, turning on the charging branch; or
in response to that the voltage signal of the charging capacitor is less than the high voltage reference value and/or the turn-on duration of the charging branch reaches the preset duration, turning off the charging branch is turned off.

19. A switching power supply of the self-powered circuit based on DCM according to claim 1, comprising:
a transformer;
an output control module configured to improve load regulation; and
the self-powered circuit configured to supply power to the output control module;
wherein the transformer comprises the primary coil, a secondary coil and an auxiliary coil;
the output control module comprises the switching power supply chip configured to output the control signal;
the self-powered circuit comprises the voltage-resistant switching transistor, the charging branch and the charging control unit; and
the voltage-resistant switching transistor is connected between the charging branch and the primary coil, the charging branch is connected in series with the voltage-resistant switching transistor, and the charging control unit is coupled between the output control module and the primary coil.

20. A switching power supply of the self-powered circuit based on CCM according to claim 8, comprising:
a transformer;
an output control module configured to improve load regulation; and
a self-powered circuit configured to supply power to the output control module;
wherein the transformer comprises the primary coil, a secondary coil and the auxiliary coil;
the output control module comprises the switching power supply chip configured to output the control signal;
the self-powered circuit comprises the voltage-resistant switching transistor, the charging branch, the mode switching unit and the charging control unit; and
the voltage-resistant switching transistor is connected between the charging branch and the primary coil, the charging branch is connected in series with the voltage-resistant switching transistor, the mode switching unit is coupled between the charging branch and the auxiliary coil, and the charging control unit is coupled between the mode switching unit and the primary coil.
